(19) United States
(12) Patent Application Publication
(10) Pub. No.: US 2012/0191902 A1
(43) Pub. Date: Jul. 26, 2012

(54) One-Die Flotox-Based Combo Non-Volatile Memory

(75) Inventors: Peter Wung Lee, Saratoga, CA (US); Fu-Chang Hsu, San Jose, CA (US)

(73) Assignee: APLUS FLASH TECHNOLOGY, INC., San Jose, CA (US)

(21) Appl. No.: 13/356,897

(22) Filed: Jan. 24, 2012

Related U.S. Application Data
(60) Provisional application No. 61/462,045, filed on Jan. 24, 2011.

(51) Int. Cl. G06F 12/02; G11C 16/04

(52) U.S. Cl. 711/103; 365/185.18; 711/E12.008

(57) ABSTRACT

A memory access apparatus that controls access to at least one memory array has an array of programmable comparison cells that retain a programmed pass code and compare it with an access pass code. When there is a match between the access pass code and the programmed pass code, the memory access apparatus generates a match signal for allowing access to the at least one memory array. If there is no match, the data within the at least one memory array may be corrupted or destroyed. Each nonvolatile comparison cell has a pair of series connected charge retaining transistors. The programmed pass code is stored in the charge retaining transistors. Primary and complementary query pass codes are applied to the charge retaining transistors and are logically compared with the stored pass code and based on the programmed threshold voltage levels determine if the query pass code is correct.

This application claims priority under 35 U.S.C. §119 to U.S. Provisional Patent Application Ser. No. 61/462,045, filed on Jan. 24, 2011, assigned to the same assignee as the present disclosure, and incorporated herein by reference in its entirety.

### BACKGROUND

1. Technical Field

This present disclosure relates generally to nonvolatile memory circuits, arrays, systems and methods of operation. More particularly, this present disclosure relates to nonvolatile floating gate transistor memory circuits, arrays, systems and methods of operation. Even more particularly, this present disclosure relates to integrated circuits containing combinations of nonvolatile floating gate transistor memory circuits and arrays and methods for operating the integrated circuits that incorporate security circuits and methods for operating the security circuits for the protection of data stored in the nonvolatile floating gate transistor memories.

2. Background

Nonvolatile memory is well known in the art. The different types of nonvolatile memory that employ a charge retention mechanism include Read-Only-Memory (ROM), Electrically Programmable Read Only Memory (EPROM), Electrically Erasable Programmable Read Only Memory (EEPROM), NOR Flash Memory, and NAND Flash Memory. The charge retention mechanism may be charge storage, as in a floating gate memory cell, and charge trapping, as in a Silicon-Oxide-Nitride-Oxide-Silicon (SONOS) or Metal-Oxide-Nitride-Oxide-Silicon (MONOS) memory cell

Typically, the NAND Flash memory structure, the NOR Flash memory structure, EEPROM memory structures are targeted three different storage markets and technologies are not compatible. The NAND Flash memory has been extensively used as a slow-serial-read, extreme-high-density, block-alterable memory array for huge data storage. Conversely, the NOR Flash memory is used as a fast-random-read medium-high-density, sector-alterable memory array for program code storage. Unlike the NAND and NOR Flash memories, the EEPROM memory is broadly used as a fast-random-read, byte-alterable memory array for small data storage.

In the past years, the market for nonvolatile memory has strongly demanded a low-cost hybrid storage solution that allows code and data to be integrated on a same die. Most of the designs were based on Flash NAND and NOR technology that has a wide variety in cell structures, program and erase schemes, and manufacturing processes. None of the previous designs are based on the mainstream two-transistor FLOTOX EEPROM memory technology. As a result, the Flash based combination structures are unable to meet EEPROM memory array reliability requirements of 1 million program/erase cycles in units of byte for 10-year product cycle. The Flash-based combination nonvolatile memory chips are able to meet the reliability criteria of the EEPROM memory now and for-seeable future. In other words, Flash-based combination memories currently are more focused for a Block-alterable, code-oriented design, rather than a byte-alterable data-oriented, solution. There is a need in the market for a byte-alterable and data oriented combination of NAND, NOR, and EEPROM integrated on to one semiconductor substrate die.

Computer based devices such as “smart cards”, smart phones, personal digital assistants, computer tablets, and other computational applications contain a large amount of sensitive information such as passwords, secure private keys, biometric data and the like that must remain secure for providing access to other data stored on the device. This secure sensitive personal information is maintained in the memories of these devices. In many cases, the memory is a nonvolatile memory such as a Flash random access memory that additionally contains the computer code for these devices.

Presently, these secure microcontrollers provide quick and mainly secure methods for authenticating users to provide access to sensitive data. The microcontrollers generally have embedded memory that stores a reference pattern of the secure sensitive information. The special cryptographic-processing units within the secure microcontrollers simply compare input data patterns entered for or by the user with stored sensitive data patterns read during the authentication cycle.

This traditional architecture presents some limitations. Traditional nonvolatile memories that are commonly used in secure applications tend to be slow. This potentially exposes the stored keys to hackers during the process. An attack may not always be detected before the full completion of the authentication cycle, creating potential security breaches.

In a traditional authentication system, the sensitive data patterns are stored in a nonvolatile memory such as a NOR flash or EEPROM. The sensitive data patterns are read from the nonvolatile memory and transferred to the special cryptographic-processing unit for comparing the stored sensitive secure data pattern with the input data patterns for authentication. During this time the data will reside in a cache region that may be accessed by a skilled “hacker”.

### SUMMARY

An object of this disclosure is to provide a device for controlling access to a memory structure to prevent unauthorized access to the memory structure.

Another object of this disclosure is to provide a device that controls access to a memory structure that when unauthorized access is attempted, reject the request for access or allows the access but corrupts or destroys the accessed data in the memory structure.

Another object of this disclosure is to provide a two-transistor FLOTOX-based Flash Programmed Logic Device (PLD) security nonvolatile memory cell.

Still, another object of this disclosure is to provide an array of two-transistor FLOTOX-based Flash PLD security nonvolatile memory cells for authentication of input data for providing security access to at least one FLOTOX based nonvolatile memory array.

At least one object is accomplished in some embodiments, with a memory access control apparatus for controlling access to a memory device. The memory access control apparatus is in communication with the memory device circuitry to control writing data to and reading data from the memory device. The memory access control apparatus has an array of nonvolatile programmable comparison cells that are connected to external circuits through primary variable input terminals and complementary variable input terminals to receive an initializing pass code that is retained as a programmed pass code for allowing access to the memory device. The memory access control apparatus receives an access request pass code that is compared with the programmed pass code. If there is a match between the access request pass code and the programmed pass code, the memory access control apparatus generates a match signal for allowing access to the memory device. If there is no match between the access request pass code and the programmed pass code, the memory access control apparatus does not generate a match signal and the request for access is rejected. In various embodiments, if the access request pass code and programmed pass code do not match, the memory access control apparatus generated signals that corrupt or destroy the data within the memory device.

In some embodiments, the memory access control apparatus is connected to bit lines of the memory device and provides the necessary bit line signals for erasing, programming, and reading the memory device when the access request pass code matches the programmed pass code. When the access request pass code and the programmed pass code do not match, the memory access control apparatus generates voltage signals on the bit lines that corrupt or destroy the data within the memory device.

In various embodiments, at least one object is accomplished by a NAND-like two-transistor FLOTOX-based security nonvolatile PLD cell formed of a pair of charge retaining FLOTOX transistors connected in a series string. A drain of a topmost charge retaining FLOTOX transistor, of the NAND-like two-transistor FLOTOX-based security nonvolatile PLD cell is connected to a product term bit line associated with and parallel to a column on which each NAND-like two-transistor FLOTOX-based security nonvolatile PLD cell resides. A source of a bottommost of the charge retaining FLOTOX transistors of each of the NAND-like two-transistor FLOTOX-based security nonvolatile PLD cell is connected to a product term source line associated with the associated NAND-like two-transistor FLOTOX-based security nonvolatile PLD cell and parallel with the associated product term bit line. The control gate of each of the charge retaining FLOTOX transistors is connected to a variable input line. Signals applied to the control gates are logically combined based on the programmed threshold voltage levels determined by the retained charge. The source of the topmost charge retaining FLOTOX transistor and the drain of the bottommost charge retaining FLOTOX transistor are commonly merged in a single drain/source region.

In each of the charge retaining FLOTOX transistors, a floating gate is formed of a first polycrystalline silicon layer over a tunneling insulation layer. The tunneling insulation layer allows charges to tunnel between the drain region and a channel region between the drains and the sources and the floating gate during programming and erasing the NAND-like two-transistor FLOTOX-based security nonvolatile PLD cell.

A control gate is formed of a second polycrystalline silicon layer on an interlayer dielectric placed over the floating gate of each FLOTOX transistor of the NAND-like two-transistor FLOTOX-based security nonvolatile PLD cell. Each of the control gates is connected to a separate variable input line for applying an input logic variable to each FLOTOX transistor of the FLOTOX-based security nonvolatile PLD cell. The variable input is a primary variable input and its complementary input variable. The FLOTOX-based security nonvolatile PLD cell is programmed such that the topmost FLOTOX transistor is written with a first state and the bottommost FLOTOX transistor is written with a second state for a first programmed code. Conversely, the topmost FLOTOX transistor is written with the second state and the bottommost FLOTOX transistor is written with the first state for a second programmed code. In operation, a query pass code is applied as the primary variable input and the complementary variable input to the control gates of the FLOTOX transistors of the FLOTOX-based security nonvolatile PLD cell. The product term source line connected to the source of the bottommost FLOTOX transistor is placed at a first voltage level that in various embodiments is the ground reference voltage level. The product term bit line connected to the drain of the topmost FLOTOX transistor is place at a second voltage level that is approximately 1.0V. If the query pass code is correct, the product term bit line connected to the FLOTOX transistor remains at the second voltage level. If the query pass code, is incorrect, the FLOTOX transistors of the FLOTOX-based security nonvolatile PLD cell conduct and the product term bit line connected to the drain of the topmost FLOTOX transistor approaches the first voltage level.

In some embodiments, the product term bit line of the FLOTOX-based security nonvolatile PLD cell are in communication directly to a bit line connected to nonvolatile memory transistors of at least one array of the nonvolatile memory cells. If the query pass code is correct, the data to be read or written is accessed correctly. If the query pass code is incorrect, the data to be read or written is corrupted and/or destroyed. In other embodiments, the product term bit line is connected to a matching circuit to generate a match signal. The match signal is active if the query pass code is correct and the match signal is inactive if the query pass code is incorrect.

In some embodiments, the control gates of the FLOTOX-based security nonvolatile PLD, cell are in communication directly to a pair of bit lines of nonvolatile memory transistors of other arrays of the nonvolatile memory cells. The product term bit line is connected to a matching circuit and a match signal is active if the query pass code is correct and the match signal is inactive if the query pass code is incorrect. If the query pass code is correct, the data to be read or written is accessed correctly. If the query pass code is incorrect, the data to be read or written is corrupted and destroyed. In various embodiments, the primary variable input and its complementary variable input are applied to the control gates of the FLOTOX-based security nonvolatile PLD cell through the bit lines of the other arrays of the nonvolatile memory cells for programming the FLOTOX-based security nonvolatile PLD cell with an initializing pass code and for comparing the programmed pass code to an query access pass code.

At least another object is accomplished with an array of NAND-like two-transistor FLOTOX-based security nonvolatile PLD cells arranged in rows and columns. The FLOTOX-based security nonvolatile PLD cells are each formed of a pair of charge retaining FLOTOX transistors connected in a series string.

A drain of a topmost charge retaining FLOTOX transistor of the NAND-like two-transistor FLOTOX-based security nonvolatile PLD cell on each column of FLOTOX-based security nonvolatile PLD cells is connected to a product term bit line associated with and parallel to the column of NAND-like two-transistor FLOTOX-based security nonvolatile PLD cells. A source of a bottommost of the charge retaining FLOTOX transistors of each of the NAND-like two-transistor FLOTOX-based security nonvolatile PLD cells is connected to a product term source line associated with the associated NAND-like two-transistor. FLOTOX-based security nonvolatile PLD cells and parallel with the associated product term bit line. The control gate of each of the charge retaining FLOTOX transistors is connected to a variable input line. Signals applied to the control gates are logically combined based on the programmed threshold voltage levels determined by the retained charge. The source of the topmost charge retaining FLOTOX transistor and the drain of the bottommost charge retaining FLOTOX transistor of each of the FLOTOX-based security nonvolatile PLD cells are commonly merged in a single drain/source region.

In each of the charge retaining FLOTOX transistors, a floating gate is formed of a first polycrystalline silicon layer over a tunneling insulation layer. The tunneling insulation layer allows charges to tunnel between the drain region and a channel region between the drains and the sources and the floating gate during programming and erasing the NAND-like two-transistor FLOTOX-based security nonvolatile PLD cell.

A control gate is formed of a second polycrystalline silicon layer on an interlayer dielectric placed over the floating gate of each FLOTOX transistor of the NAND-like two-transistor FLOTOX-based security nonvolatile PLD cells. Each of the control gates of each of the FLOTOX transistors on a row of the FLOTOX-based security nonvolatile PLD cell is connected to a separate variable input line for applying an input logic variable to each FLOTOX transistor of the FLOTOX-based security nonvolatile PLD cell. The input logic variable is a primary variable input and its complementary input variable. Each of the FLOTOX-based security nonvolatile PLD cells is programmed such that the topmost FLOTOX transistor is written with a first state and the bottommost FLOTOX transistor is written with a second state for a first programmed code. Conversely, the topmost FLOTOX transistor is written with the second state and the bottommost FLOTOX transistor is written with the first state for a second programmed code. In operation, a query pass code is applied as the primary variable input, and the complementary variable input to the control gates of the FLOTOX transistors of the FLOTOX-based security nonvolatile PLD cells. The product term source line connected to the source of the bottommost FLOTOX transistor of each of the FLOTOX-based security nonvolatile PLD cell FLOTOX-based security nonvolatile PLD cell is placed at a first voltage level that in various embodiments is the ground reference voltage level. The product term bit line connected to the drain of the topmost FLOTOX transistors of each of the FLOTOX-based security nonvolatile PLD cell is placed at a second voltage level that is approximately 1.0V. If the query pass code is correct, the product term bit line connected to the FLOTOX transistors on each column of the FLOTOX-based security nonvolatile PLD cells remains at the second voltage level. If the query pass code is incorrect, the FLOTOX transistors of the FLOTOX-based security nonvolatile PLD cells on each column conduct and the product term bit line connected to the drain of the topmost FLOTOX transistor is placed at the first voltage level.

In some embodiments, the product term bit lines of the FLOTOX-based security nonvolatile PLD array are in communication with the bit lines of at least one other nonvolatile memory array. If the query pass code is correct, the data to be read or written is accessed correctly. If the query pass code is incorrect, the data to be read or written is corrupted and destroyed. In other embodiments, the product term bit line is connected to a matching circuit and a match signal is active if the query pass code is correct and the match signal is inactive if the query pass code is incorrect.

In some embodiments, the variable input lines of the array of FLOTOX-based security nonvolatile PLD cell are in communication with the bit lines of at least one other nonvolatile memory array. The at least one other nonvolatile memory array may be a NAND Flash memory array, a one-transistor or two-transistor NOR Flash memory array, or an EEPROM memory array. If the query pass code is correct, the data to read or written is accessed correctly. If the query pass code is incorrect, the data to be read or written is corrupted and destroyed. The product term bit line of each of the columns of the FLOTOX-based security nonvolatile PLD cells is connected to a matching circuit to generate a match signal. The match signal is active if the query pass code is correct and the match signal is inactive if the query pass code is incorrect.

At least another object is accomplished with an integrated circuit having a security nonvolatile PLD array in communication with at least one nonvolatile memory array where the at least one nonvolatile memory array is a NAND Flash memory array, a one-transistor or two transistor NOR Flash memory array, or an EEPROM memory array.

The security nonvolatile PLD array is formed of NAND-like two-transistor FLOTOX-based security nonvolatile PLD cells arranged in rows and columns. The FLOTOX-based security nonvolatile PLD cells are each formed of a pair of charge retaining FLOTOX transistors connected in a series string.

A drain of a topmost charge retaining FLOTOX transistor of the NAND-like two-transistor FLOTOX-based security nonvolatile PLD cell on each column of FLOTOX-based security nonvolatile PLD cells is connected to a product term bit line associated with and parallel to the column of NAND-like two-transistor FLOTOX-based security nonvolatile PLD cells. A source of a bottommost of the charge retaining FLOTOX transistors of each of the NAND-like two-transistor FLOTOX-based security nonvolatile PLD cells is connected to a product term source line associated with the associated NAND-like two-transistor FLOTOX-based security nonvolatile PLD cells and parallel with the associated product term bit line. The control gate of each of the charge retaining FLOTOX transistors is connected to a variable input line. Signals applied to the control gates are logically combined based on the programmed threshold voltage levels determined by the retained charge. The source of the topmost charge retaining FLOTOX transistor and the drain of the bottommost charge retaining FLOTOX transistor of each of the FLOTOX-based security nonvolatile PLD cells are commonly merged in a single drain/source region.

In each of the charge retaining FLOTOX transistors, a floating gate is formed of a first polycrystalline silicon layer over a tunneling insulation layer. The tunneling insulation layer allows charges to tunnel between the drain region and a channel region between the drains and the sources and the floating gate during programming and erasing the NAND-like two-transistor FLOTOX-based security nonvolatile PLD cell.

A control gate is formed of a second polycrystalline silicon layer on an interlayer dielectric placed over the floating gate of each FLOTOX transistor of the NAND-like two-transistor FLOTOX-based security nonvolatile PLD cells. Each of the control gates of each of the FLOTOX transistors on a row of the FLOTOX-based security nonvolatile PLD cell is connected to a separate variable input line for applying an input logic variable to each FLOTOX transistor of the FLOTOX-based security nonvolatile PLD cell. The input logic variable is a primary variable input and its complementary input variable. Each of the FLOTOX-based security nonvolatile PLD cells is programmed such that the topmost FLOTOX transistor is written with a first state and the bottommost FLOTOX transistor is written with a second state for a first programmed code. Conversely, the topmost FLOTOX transistor is written with the second state and the bottommost FLOTOX transistor is written with the first state for a second programmed code. In operation, a query pass code is applied as the primary variable input and the complementary variable input to the control gates of the FLOTOX transistors of the FLOTOX-based security nonvolatile PLD cells. The product term source line connected to the source of the bottommost FLOTOX transistor of each of the FLOTOX-based security nonvolatile PLD cell FLOTOX-based security nonvolatile PLD cell is placed at a first voltage level that in various embodiments is the ground reference voltage level. The product term bit line connected to the drain of the topmost FLOTOX transistors of each of the FLOTOX-based security nonvolatile PLD cell is placed at a second voltage level that is approximately 1.0V. If the query pass code is correct, the product term bit line connected to the FLOTOX transistors on each column of the FLOTOX-based security nonvolatile PLD cells remains at the second voltage level. If the query pass code is incorrect, the FLOTOX transistors of the FLOTOX-based security nonvolatile PLD cells on each column conduct and the product term bit line connected to the drain of the topmost FLOTOX transistor is placed at the first voltage level.

In some embodiments, the product term bit lines of the FLOTOX-based security nonvolatile PLD array are in communication with the bit lines of the at least one other nonvolatile memory array. If the query pass code is correct, the data to be read or written is accessed correctly. If the query pass code is incorrect, the data to be read or written is corrupted and destroyed. In other embodiments, the product term bit line is connected to a matching circuit and a match signal is active if the query pass code is correct and the match signal is inactive if the query pass code is incorrect.

In some embodiments, the variable input lines of the array of FLOTOX-based security nonvolatile PLD cell are in communication with the bit lines of the at least one other nonvolatile memory array. The at least one other nonvolatile memory array may be a NAND Flash memory array, a one-transistor or two-transistor NOR Flash memory array, or an EEPROM memory array. If the query pass code is correct, the data to read or written is accessed, correctly. If the query pass code is incorrect, the data to be read or written is corrupted and destroyed. The product term bit line of each of the columns of the FLOTOX-based security nonvolatile PLD cells is connected to a matching circuit to generate a match signal. The match signal is active if the query pass code is correct and the match signal is inactive if the query pass code is incorrect.

In various embodiments, an isolation circuit is placed between the security nonvolatile PLD array and the at least one nonvolatile memory array. The isolation circuit is activated during programming and erasing operations of the security nonvolatile PLD array or the at least one nonvolatile memory array to prevent disturbances of the pass code data or the data resident in the at least one nonvolatile memory array. The isolation circuit has isolation transistors connected between the variable input lines or product term bit lines, dependent upon configuration, of the security nonvolatile PLD array and the bit lines of the at least one nonvolatile memory array. The control gates are in communication with a control circuit to receive an isolation signal that when active turns off the isolation transistors.

In various embodiments, a buffer circuit is in communication with the product term bit lines or variable input lines of the security nonvolatile PLD array and with the bit lines of the at least one nonvolatile memory array. The buffer circuit has sense latching circuits for capturing data to written or read from the security nonvolatile PLD array or the at least one nonvolatile memory array. If the pass code is correct, the data is written or read from the at least one nonvolatile memory array. If the pass code is incorrect, the data from the security nonvolatile PLD array, corrupts the data to be written or read to the at least one nonvolatile memory array to prevent access to the data. If the data is to be written to the at least one nonvolatile memory array and the pass code is incorrect, a copy of the data must be, stored securely because the incorrect pass code will cause destruction of the data to be written.

In still other embodiments that accomplish at least one of the objects a method of operating a provided integrated circuit having a security nonvolatile PLD array in communication with at least one nonvolatile memory array. The at least one nonvolatile memory array is a NAND Flash memory array, a one-transistor or two transistor NOR Flash memory array, or an EEPROM memory array. The security nonvolatile PLD array has a pass code written to be stored in the security nonvolatile PLD array.

The security nonvolatile PLD array is formed of NAND-like two-transistor FLOTOX-based security nonvolatile PLD cells arranged in rows and columns. The FLOTOX-based security nonvolatile PLD cells are each formed of a pair of charge retaining FLOTOX transistors connected in a series string.

A drain of a topmost charge retaining FLOTOX transistor of the NAND-like two-transistor FLOTOX-based security nonvolatile PLD cell on each column of FLOTOX-based security nonvolatile PLD cells is connected to a product term bit line associated with and parallel to the column of NAND-like two-transistor FLOTOX-based security nonvolatile PLD cells. A source of a bottommost of the charge retaining FLOTOX transistors of each of the NAND-like two-transistor FLOTOX-based security nonvolatile PLD cells is connected to a product term source line associated with the associated. NAND-like two-transistor FLOTOX-based security nonvolatile PLD cells and parallel with the associated product term bit line. The control gate of each of the charge retaining FLOTOX transistors is connected to a variable input line. Signals applied to the control gates are logically combined based on the programmed threshold voltage levels determined by the retained charge. Each of the control gates of each of the FLOTOX transistors on a row of the FLOTOX-based security nonvolatile PLD cell is connected to a separate variable input line for applying an input logic variable to each FLOTOX transistor of the FLOTOX-based, security nonvolatile PLD cell. The input logic variable is a primary variable input and its complementary input variable. Each of the FLOTOX-based security nonvolatile PLD cells is programmed such that the topmost FLOTOX transistor is written with a first state and the bottommost FLOTOX transistor is written with a second state for a first programmed code. Conversely, the topmost FLOTOX transistor is written with the second state and the bottommost FLOTOX transistor is written with the first state for a second programmed code. In operation, a query pass code is applied as the primary variable input and the complementary variable input to the control gates of the FLOTOX transistors of the FLOTOX-based security nonvolatile PLD cells. The product term source line connected to the source of the bottommost FLOTOX transistor of each of the FLOTOX-based security nonvolatile PLD cell FLOTOX-based security nonvolatile PLD cell is placed at a first voltage level that in various embodiments is the ground reference voltage level. The product term bit line connected to the drain of the topmost FLOTOX transistors of each of the FLOTOX-based security nonvolatile PLD cell is placed at a second voltage level that is approximately 1.0V.

A query pass code is applied to the variable input lines of the security nonvolatile PLD array. If the query pass code is correct, the FLOTOX transistors of each column of the FLOTOX-based security nonvolatile PLD cells remains at the second voltage level. If the query pass code is incorrect, the FLOTOX transistors of each column of the FLOTOX-based security nonvolatile PLD cells conduct and the product term bit lines connected to the drain of the topmost FLOTOX transistors are placed at the first voltage level.

In some embodiments, the product term bit lines of the FLOTOX-based security nonvolatile PLD array are in communication with the bit lines of the at least one other nonvolatile memory array. If the query pass code is correct, the data to be read or written is accessed correctly. If the query pass code is incorrect, the data to be read or written is corrupted and destroyed. In other embodiments, the product term bit line is connected to a matching circuit and a match signal is active, if the query pass code is correct and the match signal is inactive if the query pass code is incorrect.

In some embodiments, the variable input lines of the array of FLOTOX-based security nonvolatile PLD cells are in communication with the bit lines of the at least one other nonvolatile memory array. The at least one other nonvolatile memory array may be a NAND Flash memory array, a one-transistor or two-transistor NOR Flash memory array, or an EEPROM memory array. If the query pass code is correct, the data to read or written is accessed correctly. If the query pass code is incorrect, the data to be read or written is corrupted and destroyed. The product term bit line of each of the columns of the FLOTOX-based security nonvolatile PLD cells is connected to a matching circuit to generate a match signal. The match signal is active if the query pass Code is correct and the match signal is inactive if the query pass code is incorrect.

In various embodiments, an isolation circuit is placed between the security nonvolatile PLD array and the at least one nonvolatile memory array. The method continues with activating the isolation circuit during programming and erasing operations of the security nonvolatile PLD array or the at least one nonvolatile memory array to prevent disturbances of the pass code data or the data resident in the at least one nonvolatile memory array. The isolation circuit has isolation transistors connected between the variable input lines or product term bit lines, dependent upon configuration, of the security nonvolatile PLD array and the bit lines of the at least one nonvolatile memory array. The control gates are in communication with a control circuit to receive an isolation signal that when active turns off the isolation transistors.

In various embodiments, a buffer circuit is in communication with the product term bit lines or variable input lines of the security nonvolatile PLD array and with the bit lines of the at least one nonvolatile memory array. The buffer circuit has sense latching circuits for capturing data to written or read from the security nonvolatile PLD array or the at least one nonvolatile memory array. The method of operation continues with activating the buffer circuits for capturing the data to written or read from the security nonvolatile PLD array or the at least one nonvolatile memory array. If the pass code is correct, the data is written or read from the at least one nonvolatile memory array. If the pass code is incorrect, the data from the security nonvolatile PLD array, corrupts the data to be written or read to the at least one nonvolatile memory array to prevent access to the data. If the data is to be written to the at least one nonvolatile memory array and the pass code is incorrect, a copy of the data must be stored securely because the incorrect pass code will cause destruction of the data to be written.

### BRIEF DESCRIPTION OF THE DRAWINGS

FIG. 1a is a schematic of a security nonvolatile PLD cell embodying the principles of the present disclosure.

FIG. 1b is plot of the threshold voltages of security nonvolatile PLD cells embodying the principles of the present disclosure.

FIGS. 1c and 1d are tables of the voltage levels of two embodiments for erasing, programming, and operation of the security nonvolatile PLD cells embodying the principles of the present disclosure.

FIGS. 1e and 1f are tables of the logic states determined by the input variables and the programmed threshold values of the security nonvolatile PLD cells embodying the principles of the present disclosure.

FIG. 1g is a schematic of multiple security nonvolatile PLD cells illustrating the security function embodying the principles of the present disclosure.

FIGS. 2a and 2b are schematics of an array of security nonvolatile PLD cells embodying the principles of the present disclosure.

FIG. 3 is a schematic diagram of a first embodiment of an integrated circuit device incorporating security nonvolatile PLD array with at least one nonvolatile memory array embodying the principles of the present disclosure.

FIG. 4 is a schematic diagram of a second embodiment of an integrated circuit device incorporating security nonvolatile PLD array with at least one nonvolatile memory array embodying the principles of the present disclosure.

FIG. 5 is a schematic diagram of a third embodiment of an integrated circuit device incorporating security nonvolatile PLD array with at least one nonvolatile memory array embodying the principles of the present disclosure.

FIG. 6 is a flow chart for a first method of operation of an integrated circuit device incorporating, security nonvolatile PLD array with at least one nonvolatile memory array embodying the principles of the present disclosure.

FIG. 7 is a flow chart for a second method of operation of an integrated circuit device incorporating security nonvolatile PLD array with at least one nonvolatile memory array embodying the principles of the present disclosure.

FIG. 8 is a flow chart for a third method of operation of an integrated circuit device incorporating, security nonvolatile PLD array with at least one nonvolatile memory array embodying the principles of the present disclosure.

### DETAILED DESCRIPTION

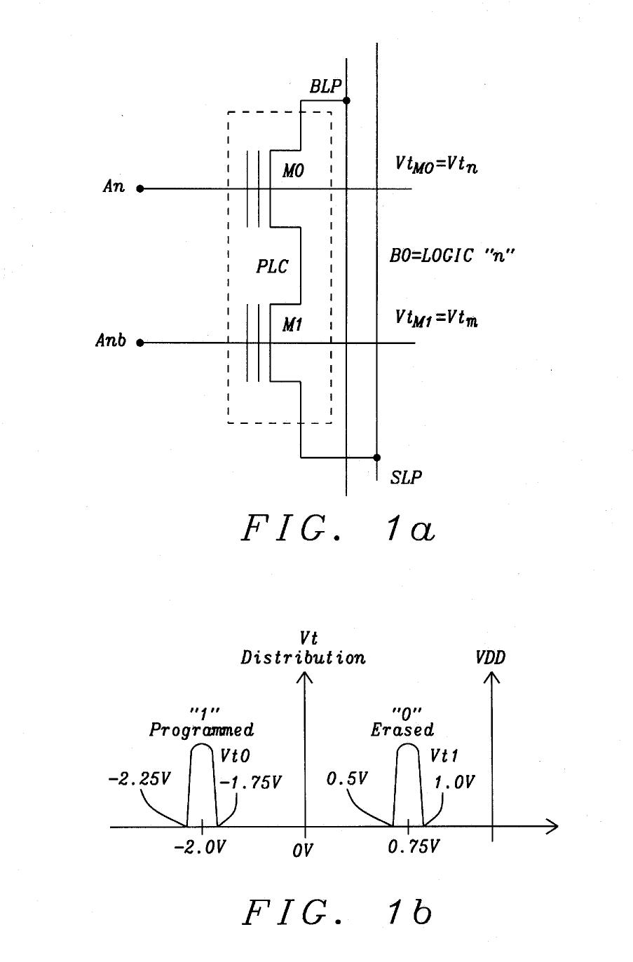

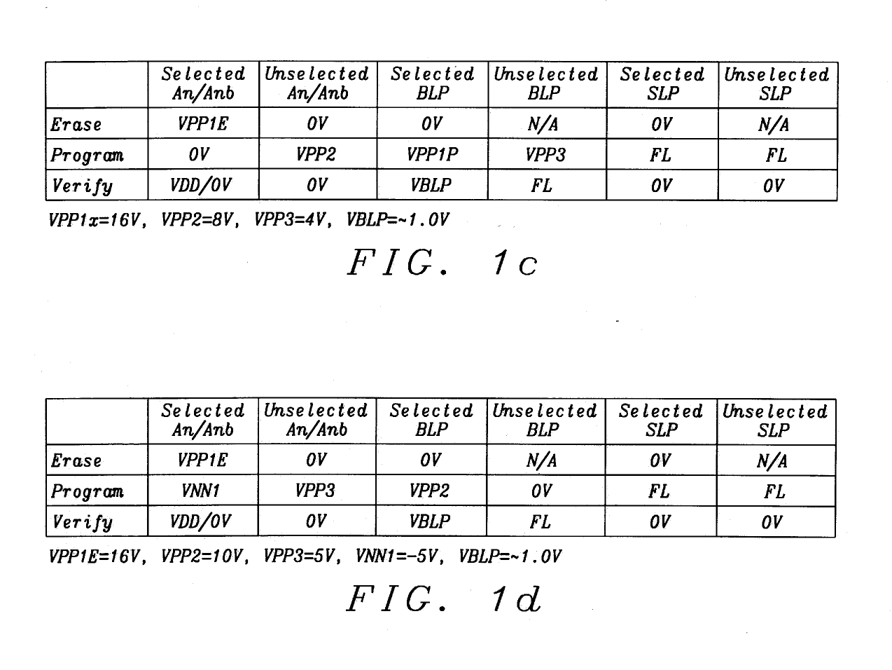

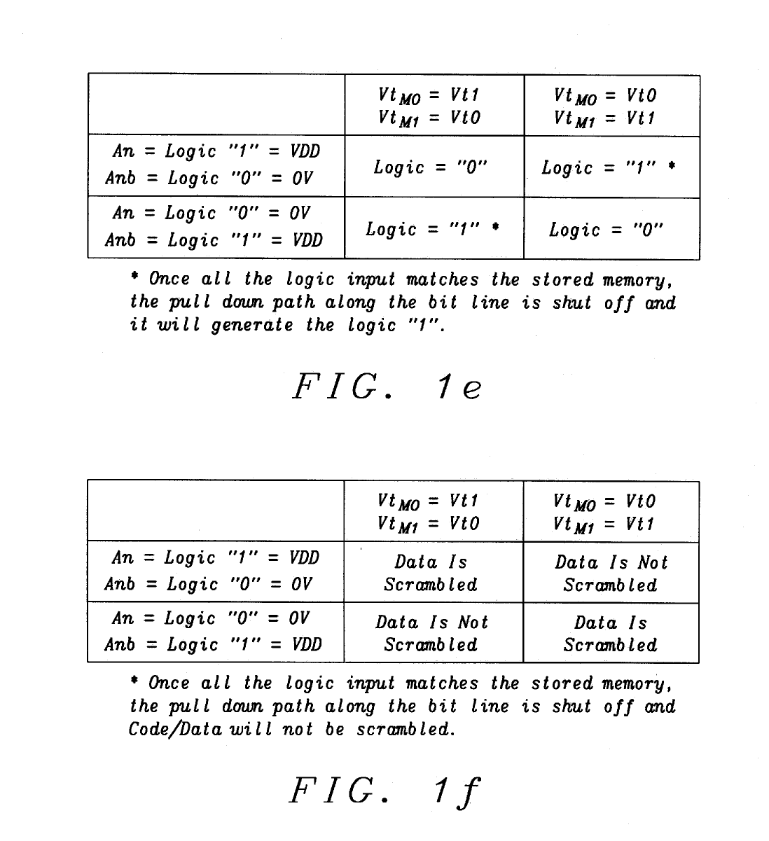

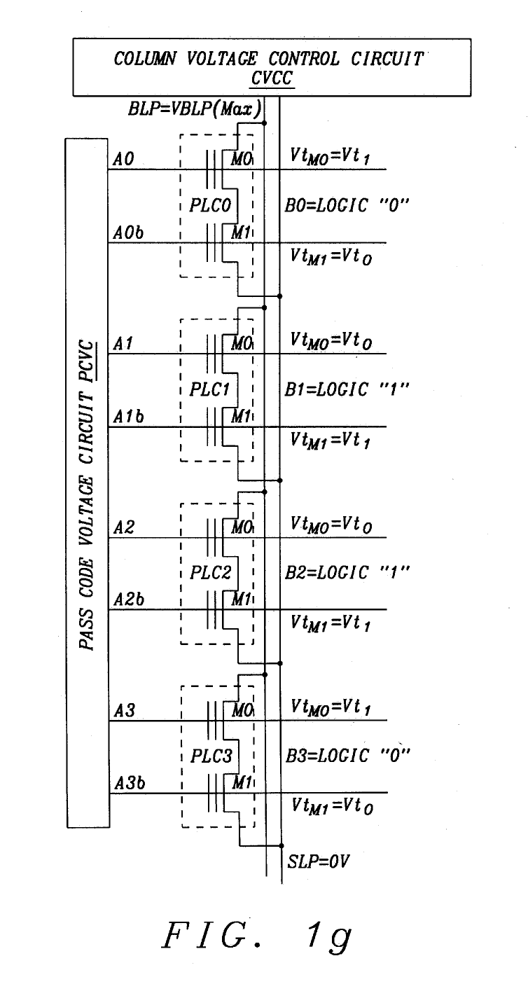

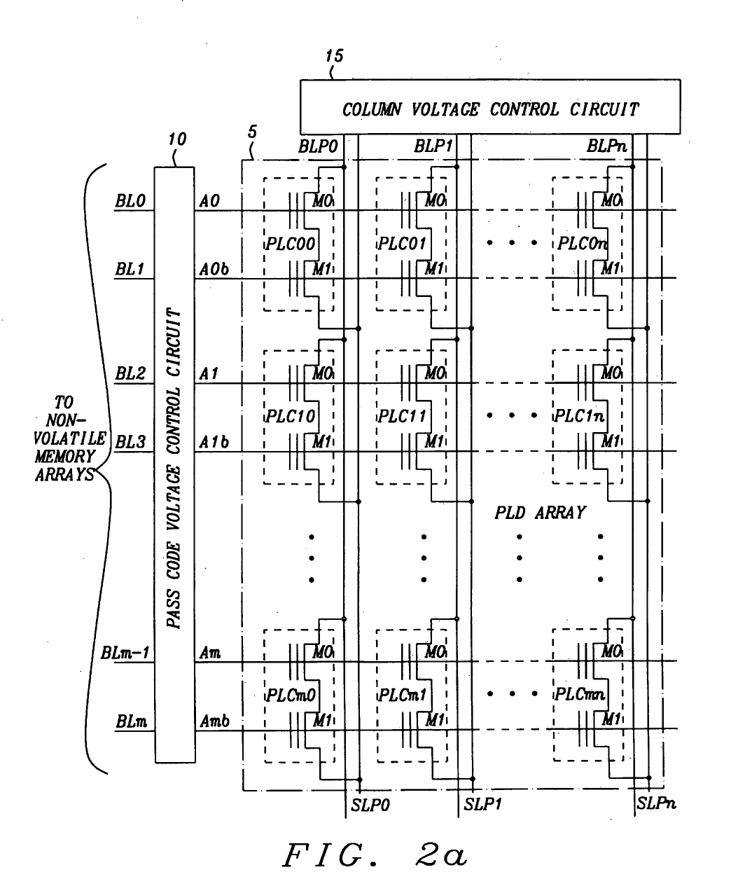

FIG. 1a is a schematic of a security nonvolatile PLD cell embodying the principles of the present disclosure. A security nonvolatile PLD cell PLC is formed of a pair of charge retaining FLOTOX transistors M0 and M1 connected in a series string. A drain of a topmost charge retaining FLOTOX transistor M0 is connected to a product term bit line BLP associated with and parallel to a column on which the nonvolatile PLD cell PLC resides. A source of a bottommost charge retaining FLOTOX transistor M1 is connected to a product term product term source line SLP associated with the associated security nonvolatile PLD cell PLC and parallel with the associated product term bit line BLP. The control gate of the charge retaining FLOTOX transistor M0 is connected to a primary variable input line An. The control gate of the charge retaining FLOTOX transistor M1 is connected to a complementary variable input line Anb. The variable input signals primary variable input line and complementary variable input line An and Anb as applied to the control gates, are logically combined based on the programmed threshold voltage levels determined by the retained charge. The source of the topmost charge retaining FLOTOX transistor M0 and the drain of the bottommost charge retaining FLOTOX transistor M1 are commonly merged in a single drain/source region.

In each of the charge retaining FLOTOX transistors M0 and M1, a floating gate is formed of a first polycrystalline silicon layer over a tunneling insulation layer. The tunneling insulation layer allows charges to tunnel between the drain region and a channel region between the drains and the sources and the floating gate during programming and erasing the NAND-like two-transistor FLOTOX-based security nonvolatile PLD cell PLC.

A control gate is formed of a second polycrystalline silicon layer on an interlayer dielectric placed over the floating gate of each FLOTOX transistor M0 and M1. Each of the control gates is connected to a separate variable input line for applying an input logic variable to each FLOTOX transistor M0 and M1 of the FLOTOX-based security nonvolatile PLD cell PLC. The variable input is a primary variable input An and its complementary variable input Anb. The FLOTOX-based security nonvolatile PLD cell is programmed such that the topmost FLOTOX transistor M0 is written with a first logic state and the bottommost FLOTOX transistor M1 is written with a second logic state for a first programmed code. Conversely, the topmost FLOTOX transistor M0 is written with the second logic state and the bottommost FLOTOX transistor M1 is written with the first logic state for a second programmed code.

FIG. 1b is plot of the threshold voltages of security nonvolatile PLD cells embodying the principles of the present disclosure. The first logic state (logic “1”) is represented with a threshold voltage value of Vt₀ and is considered the erased state. In the present embodiment, the first logic state has a voltage level of from approximately −2.25V to approximately −1.75V (nominally −2.0V). The second logic state (logic “0”) is represented with a threshold voltage value of Vt1 and is considered the programmed state. In the present embodiment, the second logic state has a voltage level of from approximately 0.5V to approximately 1V (nominally 0.75V).

FIGS. 1c and 1d are tables of the voltage levels of two embodiments for erasing, programming, and operation of the security nonvolatile PLD cell PLC embodying the principles of the present disclosure. In the two embodiments, the FLOTOX transistors M0 and M1 of the security nonvolatile PLD cell PLC erased by applying a very large positive erase voltage level VPP1E that is from approximately 15.0V to approximately 17.0V (nominally 16.0V) to the control gate of the FLOTOX transistors M0 and M1 through primary variable input line An and the complementary variable input line Anb. The control gates of unselected FLOTOX transistors M0 and M1 are connected to the ground reference voltage level 0.0V through the primary variable input line An and the complementary variable input line Anb. The product term bit line BLP and the product term source line SLP and thus the drain of the topmost FLOTOX transistor M0 and the source of the bottommost FLOTOX transistor M1 are also connected to the ground reference voltage level (0.0V). If the product term bit line BLP and the product term source line SLP are unselected, the drain of the topmost FLOTOX transistor M0 and the source of the bottommost FLOTOX transistor M1 may be selectively connected to the ground reference voltage level (0.0V) or allowed to float.

In FIG. 1c, the FLOTOX transistors M0 and M1 of the security nonvolatile PLD cell PLC programmed by applying the ground reference voltage level to the control gate of the FLOTOX transistors M0 and M1 through primary variable input An and the complementary variable input Anb. The product term bit line BLP is set to a very large positive program voltage level VPP1P that is from approximately 15.0V to approximately 17.0V (nominally 16.0V). The product term source lines SLP, selected or unselected, are disconnected and allowed to float.

When the security nonvolatile PLD cell PLC is unselected for programming, product term bit line BLP is set to a small positive program inhibit voltage level VPP3 that is from approximately 3.5V to approximately 4.5V (nominally 4.0V). The control gates of unselected FLOTOX transistors M0 and M1 are connected to a moderately large positive program inhibit voltage level VPP2 that is from approximately 7.0V to approximately 9.0V (nominally 8.0V) through the primary variable input An and the complementary variable input Anb.

In FIG. 1d, the FLOTOX transistors M0 and M1 of the security nonvolatile PLD cell PLC programmed by applying a relatively small negative program voltage level VNN1 that is from approximately −4V to approximately −6V (nominally −5.0V) to the control gate of the FLOTOX transistors M0 and M1 through primary variable input An and the complementary variable input Anb. The product term bit line BLP is set to the moderately large positive program voltage level VPP2 that is from approximately 9.0V to approximately 11.0V (nominally 10.0V). The product term source lines SLP, selected or unselected, are disconnected and allowed to float.

When the security nonvolatile PLD cell PLC is unselected for programming, product term bit line BLP is set to the ground reference voltage level (0.0V). The control gates of unselected FLOTOX transistors M0 and M1 are connected to the small positive program inhibit voltage level VPP3 that is from approximately 4.5V to approximately 5.5V (nominally 4.0V) through the primary variable input An and the complementary variable input Anb.

FIGS. 1e and 1f are tables of the logic states determined by the input variables and the programmed threshold values of the security nonvolatile PLD cell PLC embodying the principles of the present disclosure. In FIG. 1e, the first column illustrates the threshold voltage levels representing a logical “0” where the topmost FLOTOX transistor M0 is erased to the second logic state or the second threshold voltage level value Vt1 and the bottommost FLOTOX transistor M1 is programmed to the first logic state or the first threshold voltage level Vt0. If the primary variable input An is set to the voltage level of, the power supply voltage source VDD, the complementary input Anb is set to the voltage level of the ground reference voltage source (0.0V), the topmost FLOTOX transistor M0 and the bottommost FLOTOX transistor M1 are turned on to force the product term bit line to the voltage level of the product term source line VBLP(max)−δV representing the logic level “0”. Alternately, in the second row, if the primary variable input An is set to the voltage level of the ground reference voltage source (0.0V), the complementary input is set to the voltage level of the power supply voltage source VDD. The topmost FLOTOX transistor M0 is turned on and the bottommost FLOTOX transistor M1 are turned off to force the product term bit line to the logic operation voltage level VBLP(max) representing the logic level “1”

### Please Provide the Logic Operation Voltage Level VBLP for the Product Term Bit Line

The second column illustrates the threshold voltage levels representing a logical “1” where the topmost FLOTOX transistor M0 is programmed to the first logic state or the first threshold voltage level value Vt0 and the bottommost FLOTOX transistor M1 is erased to the second logic state or the second threshold voltage level Vt1. If the primary variable input An is set to the voltage level of the power supply voltage source VDD, the complementary input Anb is set to the voltage level of the ground reference voltage source (0.0V), the topmost FLOTOX transistor M0 and the bottommost FLOTOX transistor M1 are turned off to force the product term bit line to the voltage level of the logic operation voltage level VBLP(max) representing the logic level “1” that is approximately 1.0V. Alternately, in the second row, if the primary variable input An is set to the voltage level of the ground reference voltage source (0.0V), the complementary input is set to the voltage level of the power supply voltage source VDD. The topmost FLOTOX transistor M0 is turned on and the bottommost FLOTOX transistor M1 are turned on to force the voltage level of the product term bit line toward the voltage level of the product term source line. That is the voltage level product term bit dine BLP becomes the logic operation voltage level VBLP(max) less a differential voltage δV (VBLP(max)−δV). The differential voltage δV is a less than the logic operation voltage level VBLP(max) but greater than the ground reference voltage level (0.0V) of the product term source line SLP and represents the logic level “0”.

In various embodiments, where the security nonvolatile PLD cell PLC provides authentication of a pass code to allow access to at least one nonvolatile memory array, the security nonvolatile PLD cell PLC may be connected to scramble the data, if the pass code is incorrect. In FIG. 1f, if the primary variable input A and the complementary variable input Ab force the product term bit line to the logic “0”, any data read or written is scrambled and destroyed to prevent access to the data. Alternately, if the primary variable input A and the complementary variable input Ab force the product term bit line to the logic “1”, any data read or written is not, scrambled or destroyed and the data is read or written as required.

FIG. 1g is a schematic of multiple security nonvolatile PLD cells PLC0, PLC1, PLC2, and PLC3 illustrating the security function embodying the principles of the present disclosure. In this example, there are four security nonvolatile PLD cells PLC0, PLC1, PLC2, and PLC3 that are programmed with a pass code. Each of the four security nonvolatile PLD cells PLC0, PLC1, PLC2, and PLC3 have the drain of the topmost FLOTOX transistor M0 connected to the product term bit line BLP and the source of the bottommost FLOTOX transistor M1 connected to the product term source line SLP. The product term bit line BLP and the product term source line SLP are connected to the column voltage control circuit CVCC to establish the voltage levels for the product term bit line BLP and the product term source line SLP. The primary variable input lines A0, A1, A2, and A3 and the complementary variable input A0b, A1b, A2b, and A3b of the FLOTOX transistors M0 and M1 are connected to receive the primary input signals A0, A1, A2, and A3 and complementary input signals A0b, A1b, A2b, and A3b from the pass code voltage circuit PCVC

The programmed variables B0, B1, B2, and B3 of each of the four security nonvolatile PLD cells PLC0, PLC1, PLC2, and PLC3 are mapped for this example to be the binary code 0110. Thus the FLOTOX transistors M0 and M1 of the first security nonvolatile PLD cell PLC0 are respectively programmed to the second threshold voltage level Vt₁ and the first threshold voltage level Vt₀. The FLOTOX transistors M0 and M1 of the second security nonvolatile PLD cell PLC1 are respectively programmed to the first threshold voltage level Vt₀ and the second threshold voltage level Vt₁. Similarly, the FLOTOX transistors M0 and M1 of the third security nonvolatile PLD cell PLC2 are respectively programmed to the first threshold voltage level Vt₀ and the second threshold voltage level Vt₁. The FLOTOX transistors M0 and M1 of the fourth security nonvolatile PLD cell PLC3 are respectively programmed to the second threshold voltage level Vt₁ and the first threshold voltage level Vt₀.

In operation, a query pass code is applied as the primary input variable lines A0, A1, A2, and A3 and the complementary input variable A0b, A1b, A2b, and A3b to the control gates of the FLOTOX transistors M0 and M1 of the four security nonvolatile PLD cells PLC0, PLC1, PLC2, and PLC3. The column voltage control circuit CVCC sets the product term source line SLP connected to the source of the bottommost FLOTOX transistor M1 to a first voltage level that in various embodiments is the ground reference voltage level. The column voltage control circuit CVCC sets the product term bit line BLP connected to the drain of the topmost FLOTOX transistor M0 to a second voltage level VBLP(max) that is approximately 1.0V. If the query pass code is correct, the product term bit line BLP connected to the FLOTOX transistor M0 remains at the second voltage level VBLP(max). If the query pass code is incorrect, the FLOTOX transistors M0 and M1 conduct and the product term bit line BLP connected to the drain of the topmost FLOTOX transistor M0 is placed at the first voltage level that is logic operation voltage level VBLP(max) less a differential voltage δV (VBLP(max)−δV) The differential voltage δV is a less than the logic operation voltage level VBLP(max) but greater than the ground reference voltage level (0.0V) of the product term source line SLP and represents the logic level “0”.

In some embodiments, the product term bit line BLP of the four security nonvolatile PLD cells PLC0, PLC1, PLC2, and PLC3 are in communication directly to a bit line connected to nonvolatile memory transistors of at least one array of the nonvolatile memory cells. If the query pass code is correct, the data to be read or written is accessed correctly. If the query pass code is incorrect, the data to be read or written is corrupted and destroyed. In other embodiments, the product term bit line BLP is connected to a matching circuit (not shown) to generate a match signal. The match signal is active if the query pass code is correct and the match signal is inactive if the query pass code is incorrect.

In some embodiments, the control gates of the FLOTOX transistors M0 and M1 of the four security nonvolatile PLD cells PLC0, PLC1, PLC2, and PLC3 are in communication directly to a pair of bit lines of nonvolatile memory transistors of other arrays of the nonvolatile memory cells. The product term bit line BLP is connected to a matching circuit and a match signal is active if the query pass code is correct and the match signal is inactive if the query pass code is incorrect. If the query pass code is correct, the data to be read or written is accessed correctly. If the query pass code is incorrect, the data to be read or written is prevented from being accessed. In other embodiments, the data to be read or written may be corrupted or destroyed.

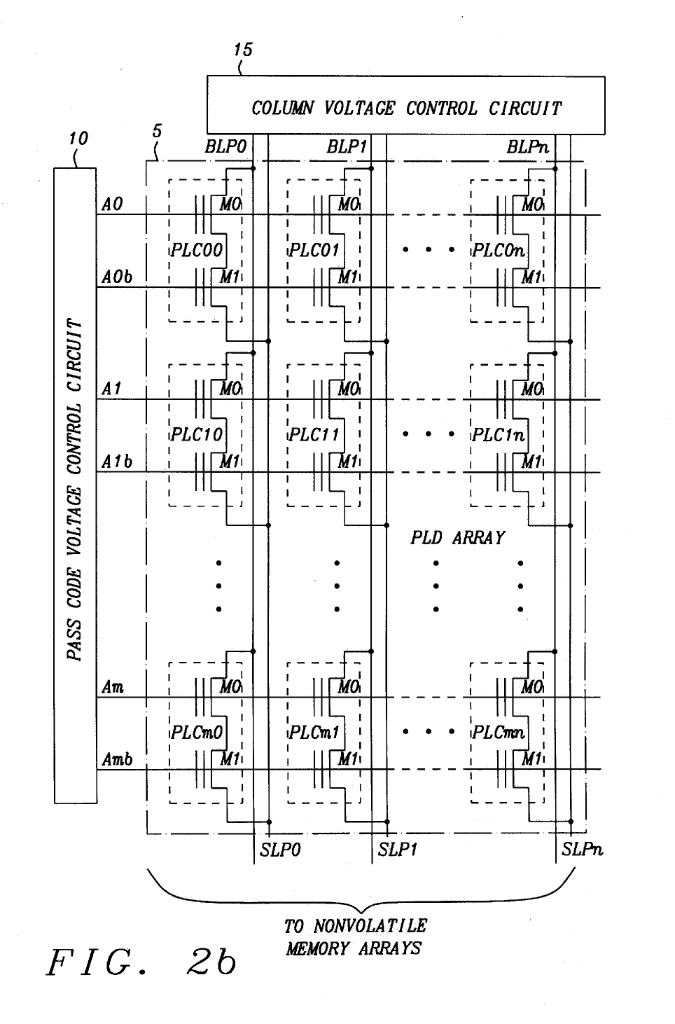

FIGS. 2a and 2b are schematics of an array 5 of security nonvolatile. PLD cells PLC00, PLC01, . . . PLCm0, . . . , PLCmn embodying the principles of the present disclosure. The security nonvolatile PLD cells PLC00, PLC01, . . . PLCm0, . . . , PLCmn are arranged in rows and columns. The control gates of each of the FLOTOX transistors M0 and M1 of the rows of security nonvolatile PLD cells PLC00, PLC01, PLCm0, . . . , PLCmn are connected to the primary variable input lines A0, A1, . . . , Am and the complementary variable input lines A0b, A1b, . . . , Amb. The primary variable input lines A0, A1, . . . , Am and the complementary variable input A0b, A1b, . . . , Amb are connected to the pass code control circuit 10. The pass code control circuit 10 develops the necessary signals that are applied to the control gates of each row of the FLOTOX transistors M0 and M1 through primary variable input lines A0, A1, . . . , Am and the complementary variable input A0b, A1b, . . . , Amb for erasing, programming, and logic operation of the security nonvolatile PLD cells PLC00, PLC01, . . . PLCm0, . . . , PLCmn.

The drain of the topmost FLOTOX transistor M0 of each of the security nonvolatile PLD cells PLC00, PLC01, PLCm0, . . . , PLCmn on each column is connected to a product term bit line BLP0, BLP1, . . . , BLPm. The product term bit lines BLP0, BLP1, . . . , BLPm are connected to the column voltage control circuit 15 to provide the necessary voltage levels for the erasing, programming and logical operations of the security nonvolatile PLD cells PLC00, PLC01, . . . PLCm0, . . . , PLCmn. Similarly, the source of the bottommost FLOTOX transistor M1 of each of the security nonvolatile PLD cells PLC00, PLC01, . . . PLCm0, . . . , PLCmn on each column is connected to a product term source line SLP0, SLP1, . . . , SLPm. The product term source lines SLP0, SLP1, SLPm are connected to the column voltage control circuit 15. The column voltage control circuit 15 to provide the necessary signals for the erasing, programming and logical operations of the security nonvolatile PLD cells PLC00, PLC01, . . . PLCm0, . . . , PLCmn.

The array 5 of the security nonvolatile PLD cells PLC00, PLC01, . . . PLCm0, . . . , PLCmn is connected to at least one nonvolatile memory array. In FIG. 2a, the bit lines of the at least one nonvolatile memory array are in communication with the primary variable input lines A0, A1, . . . , Am and the complementary variable input A0b, A1b, . . . , Amb to control access to the data of the at least one nonvolatile memory array. In FIG. 2b, the product term bit lines of the array 5 of the security nonvolatile PLD cells PLC00, PLC01, . . . PLCm0, . . . , PLCmn are in communication with the bit lines of the at least one nonvolatile memory. The at least one nonvolatile memory array may be a NAND Flash memory array, a one-transistor or two-transistor NOR Flash memory array, or an EEPROM memory array.

In operation, the pass code control circuit 10 and the column voltage control circuit 15 applies the necessary voltages as described in FIG. 1c or 1d to the primary variable input lines A0, A1, . . . , Am and the complementary variable input lines A0b, A1b, . . . , Amb and thus to the control gates of the security nonvolatile PLD cells PLC00, PLC01, . . . PLCm0, . . . , PLCmn to erase and then program the pass code to the security nonvolatile PLD cells PLC00, PLC01, . . . PLCm0, . . . , PLCmn on each column of the array 5 of the security nonvolatile PLD cells PLC00, PLC01, . . . PLCm0, . . . , PLCmn. When the at least one nonvolatile memory array is to be read from or written to, the pass code is applied to the primary variable input lines A0, A1, . . . , Am and the complementary variable input lines A0b, A1b, . . . , Amb through by the pass code voltage control circuit 10. The column voltage control circuit 15 sets the product term source lines SLP0, SLP1, . . . , SLPm to approximately the ground reference voltage and the product term bit lines BLP0, BLP1, . . . , BLPm to a product term determination voltage level as shown in FIGS. 1c or 1d. If the query pass code is correct, the data from the at least one nonvolatile memory in communication with the array 5 of the security nonvolatile PLD cells PLC00, PLC01, . . . PLCm0, . . . , PLCmn to be read or written is accessed correctly. If the query pass code is incorrect, the data to be read or written is corrupted and destroyed. In other embodiments, the product term bit lines BLP0, BLP1, . . . , BLPm are connected to a matching circuit (not shown) to generate a match signal. The match signal is active if the query pass code is correct and the match signal is inactive if the query pass code is incorrect.

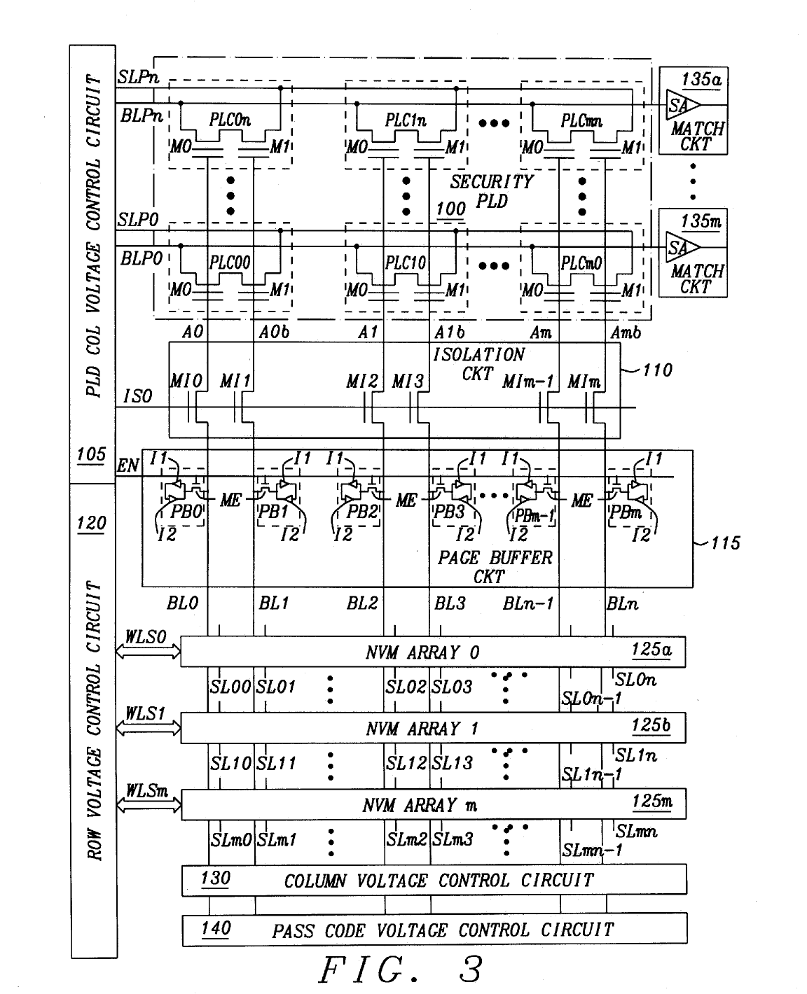

FIG. 3 is a schematic diagram of various embodiments of an integrated circuit device incorporating a security nonvolatile PLD array 100 with at least one nonvolatile memory array 125a, 125b, . . . 125m embodying the principles of the present disclosure. The array 100 is formed of multiple security nonvolatile PLD cells PLC00, PLC01, . . . PLCm0, . . . , PLCmn formed in rows and columns. The product term bit lines BLP0, . . . , BLPn and the product term source lines SLP0, . . . , SLPn are connected to the PLD column voltage control circuit to receive the necessary biasing signals for the erasing, programming, and operation of the security nonvolatile PLD array 100. Each of the product term bit lines BLP0, . . . , BLPn is connected to a matching circuit 135a, . . . , 135m. Each matching circuit 135a, . . . , 135m has a sense amp SA that determines if the pass code for the verified and the at least one nonvolatile memory array 125a, 125b, . . . , 125m is permitted to read from or written to or the pass code is not verified and the data access to the at least one nonvolatile memory array 125a, 125b, . . . , 125m is denied or the data is to be corrupted or destroyed.

The primary variable input lines A0, A1, . . . , Am and the complementary variable input lines A0b, A1b, . . . , Amb are connected to an isolation circuit 110. The isolation circuit 110 has one isolation transistor MI0, MI1, . . . , MIm connected through the drain to each of the primary variable input lines A0, A1, . . . , Am and the complementary variable input lines A0b, A1b, . . . , Amb. The isolation circuit 110 is connected to a page buffer circuit 115 and to the bit lines of at least one nonvolatile memory array 125a, 125b, . . . , 125m. The isolation circuit 115 separates the security nonvolatile PLD array 100 from the at least one nonvolatile memory array 125a, 125b, . . . , 125m during the programming and erasing to prevent disturb voltages from corrupting the pass code data of the array 100 of security nonvolatile PLD cells PLC00, PLC01, . . . PLCm0, . . . , PLCmn or the data within the at least one nonvolatile memory array 125a, 125b, . . . , 125m. The at least one nonvolatile memory arrays 125a, 125b, . . . , 125m may be a combination of NAND Flash memory arrays, a one-transistor or two-transistor NOR Flash memory arrays, or an EEPROM memory arrays.

The source of each isolation transistor MI0, MI1, . . . , MIm is connected to the bit lines of each of the at least one nonvolatile memory array 125a, 125b, . . . , 125m and to the page buffer 115. The gates of the isolation transistors MI0, MI1, . . . , MIm are connected to a isolation signal for activation and deactivation of isolation transistors MI0, MI1, . . . , MIm for the separation of the security nonvolatile PLD array 100 from the at least one nonvolatile memory arrays 125a, 125b, . . . , 125m during the erasing and programming.

The page buffer 110 has one page buffer circuit BP0, BP1, . . . , BPm connected to each of the bit lines BL0, BL2, BL3, . . . , BLn of the at least one nonvolatile memory array 125a, 125b, . . . , 125m. Each of the page buffer circuits BP0, BP1, . . . , BPm have an pair of cross connected inverters I1 and I2 to form a latching circuit to capture the data from the at least one nonvolatile memory array 125a, 125b, . . . , 125m and externally for writing to the at least one nonvolatile memory array 125a, 125b, . . . , 125m or the security nonvolatile PLD array 100. The output of one of the inverters I2 and the input of the other of the inverters I1 is connected to the drain of an enable transistor ME. The source of the enable transistor ME is connected to the associated bit line BL0, BL2, BL3, . . . , BLn. The gates of the enable transistors ME are connected to the enable line EN that is the output of the PLD column voltage control circuit 105. The enable line EN is activated during the erasing, programming, and presenting the pass code for access to the at least one nonvolatile memory array 125a, 125b, . . . , 125m. The enable line EN is deactivated to retain the data or pass code during reading of the at least one nonvolatile memory arrays 115a, 115b, . . . , 115m and performing the comparison of the applied pass code with the stored pass code of the security nonvolatile PLD array 100.

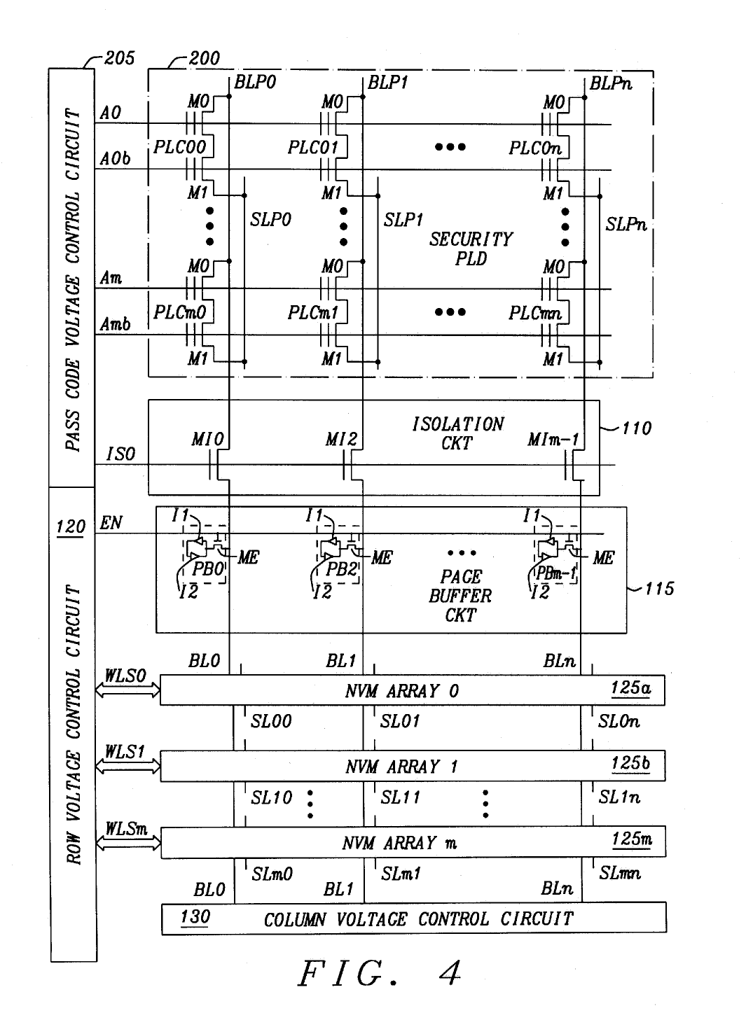

FIG. 4 is a schematic diagram of other embodiments of an integrated circuit device incorporating security nonvolatile PLD array 100 with at least one nonvolatile memory array 125a, 125b, . . . , 125m. The structure of the at least one nonvolatile memory array 125a, 125b, . . . , 125m of the present embodiment is identical to that of FIG. 3. The structural difference is that the security nonvolatile PLD array 100 is oriented orthogonally to that of FIG. 3. The primary variable input lines A0, A1, . . . , Am and the complementary variable input lines A0b, A1b, . . . , Amb are not connected to the bit lines BL0, BL2, BL3, . . . , BLn of the at least one nonvolatile memory array 125a, 125b, . . . , 125m. The bit lines BL0, BL2, BL3, . . . , BLn of the at least one nonvolatile memory array 125a, 125b, . . . , 125m are now connected to the corresponding product term bit lines BLP0, BLP1, BLPm. The primary variable input lines A0, A1, . . . , Am and the complementary variable input lines A0b, A1b, . . . , Amb are connected directly to the pass code voltage control circuit 205 that it controls a row of the security nonvolatile PLD cells PLC00, PLC01, . . . PLCm0, . . . , PLCmn. The isolation control signal ISO that controls the activation of the isolation circuit 110 is now controlled by the pass code voltage control circuit 205.

When the pass code is verified, the bit lines BL0, BL2, BL3, . . . , BLn are all placed at a voltage for so that the at least one nonvolatile memory array 125a, 125b, . . . , 125m are able to be written or read. When the pass code is not verified, the bit lines BL0, BL2, BL3, . . . , BLn are set to the voltage level of the ground reference voltage source. The data to be written to or read from at least one nonvolatile memory array 125a, 125b, . . . , 125m is corrupted or destroyed.

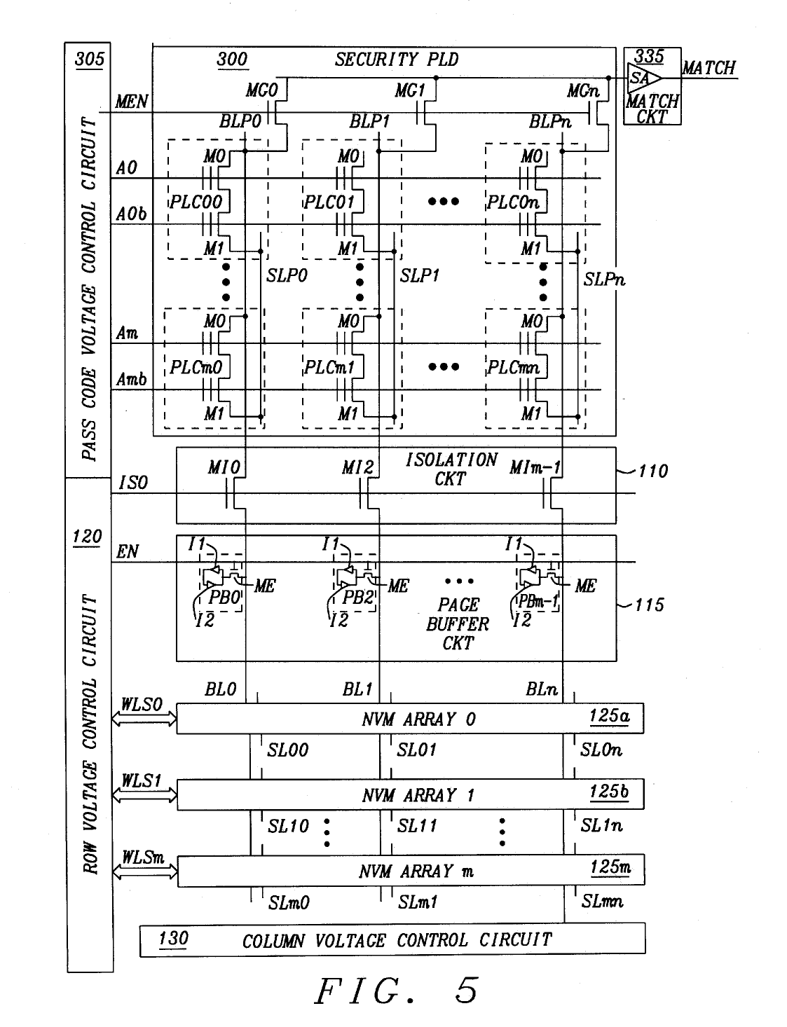

FIG. 5 is a schematic diagram of various other embodiments of an integrated circuit device incorporating security nonvolatile PLD array 100 with at least one nonvolatile memory array 125a, 125b, . . . , 125m. The structure of the at least one nonvolatile memory array 125a, 125b, . . . , 125m of the present embodiment is identical to that of FIG. 4. The security nonvolatile PLD array 100 is structured and functions as shown in FIG. 4. The difference from FIG. 4 is the addition, of the matching, circuit 335 and the match gates MG0, MG2, MG3, . . . , MGn. The drains match gate transistors MG0, MG2, MG3, . . . , MGn are commonly connected to the input of the sense amplifier SA of the match circuit 335. The match enable line. MEN connects the gates of the match gate transistors MG0, MG2, MG3, . . . , MGn to the pass code voltage control circuit 305. In operation, the pass code is applied to the product term bit line BLP0, BLP1, . . . , BLPm. If the pass code is correct, the bit lines BL0, BL2, BL3, . . . , BLn are set to the logic operation voltage level VBLP. The match enable line MEN is activated and the match circuit 335 senses the logic operation voltage level VBLP and becomes active declaring that the pass code is matched or correct. If the pass code is incorrect, the bit lines BL0, BL2, BL3, . . . , BLn are brought to the voltage level of the ground reference voltage. When the match enable line MEN is, activated, the match circuit 335 senses the ground reference voltage on the bit lines BL0, BL2, BL3, . . . , BLn and becomes inactive declaring that the pass code is incorrect or not matched. This permits the circuit to block any write or read operations to the at least one nonvolatile memory array 125a, 125b, . . . , 125m. The additional function of the match circuit 335 allows an integrated circuit employing the security nonvolatile PLD array 100 with the at least one nonvolatile memory array 125a, 125b, . . . , 125m to optionally corrupt, or destroy the data present in the at least one nonvolatile memory array 125a, 125b, . . . , 125m or to simply block any of the write or read operations to the at least one nonvolatile memory array 125a, 125b, . . . , 125m.

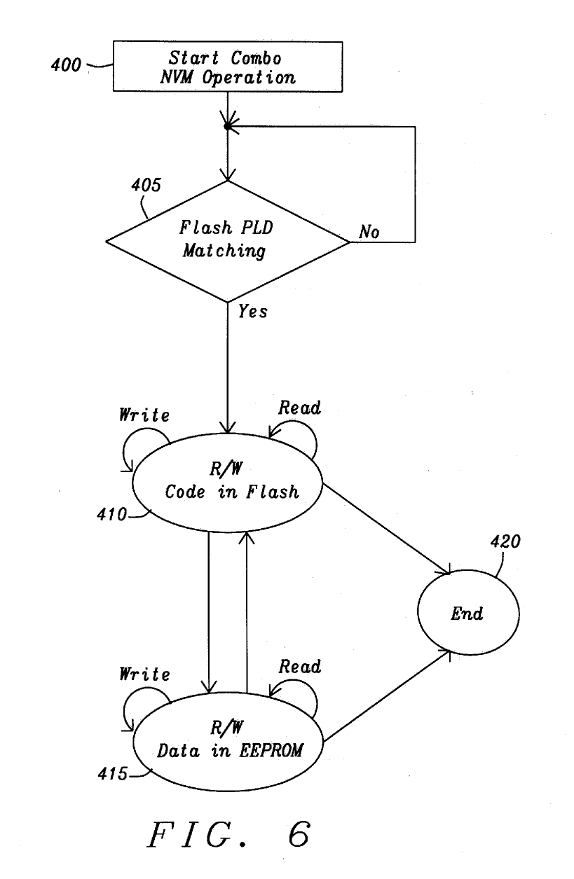

FIG. 6 is a flow chart for a first method of operation of an integrated circuit device incorporating security nonvolatile PLD array with at least one nonvolatile memory array. A combination nonvolatile memory integrated includes a security nonvolatile PLD array such as shown in FIGS. 3, 4, and 5 connected through an isolation circuit an a page buffer to at least one nonvolatile memory array. The at least one nonvolatile memory array may be a NAND Flash memory array, a one-transistor or two-transistor NOR Flash memory array, or an EEPROM memory array. The NAND flash memory may be designated to retain huge data files such as those audio and video data. The NOR flash memory array is sufficiently small and partitioned such that it is suitable for program code data storage. The EEPROM array may be designated for byte-alterable data storage. The combination nonvolatile memory integrated circuit will incorporate any or all of these functions. The method of FIG. 6 begins with the activation (Box 400) of the combination nonvolatile memory integrated circuit. The pass code is applied to the primary variable input lines and the complementary variable input lines of the security nonvolatile PLD array. The input pass code is compared (Box 405) with the pass code stored in the security nonvolatile PLD array. If the input pass code and the stored pass code match and if there is a NOR flash nonvolatile memory array containing the programming code and/or a NAND flash nonvolatile memory array containing large amounts of audio or video data, the NOR flash nonvolatile memory array is written to or read from (Box 410) as required. If there is an EEPROM memory array for byte-alterable data storage, EEPROM memory array is written to or read from (Box 415). Upon completion of the writing to or reading (Boxes 410 and 415) the operation is ended (Box 420)

If the input pass code and the stored pass code do not match (Box 405), a new pass code is requested for matching until the correct pass code is received.

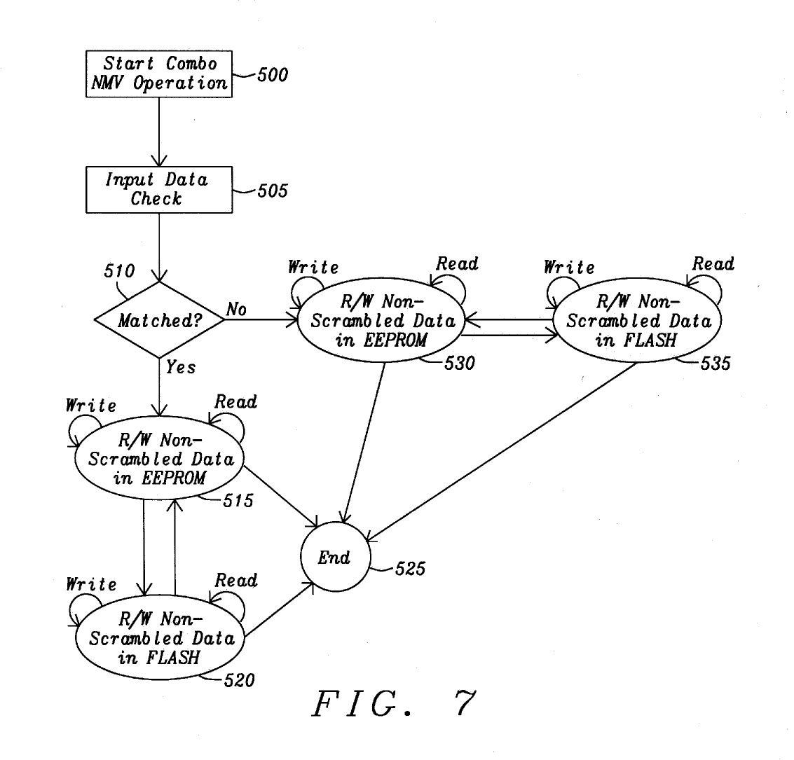

FIG. 7 is a flow chart for a second method of, operation of an integrated circuit device incorporating security nonvolatile PLD array with at least one nonvolatile memory array. A combination nonvolatile memory integrated circuit includes a security nonvolatile PLD array such as shown in FIGS. 3, 4, and 5 connected through an isolation circuit an a page, buffer to at least one nonvolatile memory array as described above. The method of FIG. 7 begins with the activation (Box 500) of the nonvolatile integrated circuit. The pass code is applied (Box 505) to the primary variable input lines and the complementary variable input lines of the security nonvolatile PLD array. The input pass code is compared (Box 510) with the pass code stored in the security nonvolatile PLD array. If the input pass code and the stored pass code match and if there is a NOR flash nonvolatile memory array containing the programming code and/or a NAND flash nonvolatile memory array containing large amounts of audio or video data, the NOR flash nonvolatile memory array is written to or read from (Box 515) as required. If there is an EEPROM memory array for byte-alterable data storage, EEPROM memory array is written to or read from (Box 520). Upon completion of the writing to or reading (Boxes 515 and 520) the operation is ended (Box 525).

If the input pass code and the stored pass code do not match (Box 510) and if there is a NOR flash nonvolatile memory array containing the programming code and/or a NAND flash nonvolatile memory array containing large amounts of audio or video data, the NOR flash nonvolatile memory array is written to or read from with scrambled or corrupted data (Box 530) to destroy the data. If there is an EEPROM memory array for byte-alterable data storage, EEPROM memory array is written to or read from with scrambled or corrupted data (Box 535) to destroy the data. Upon completion of the writing to or reading from the scrambled data(Boxes 530 and 535) the operation is ended (Box 525).

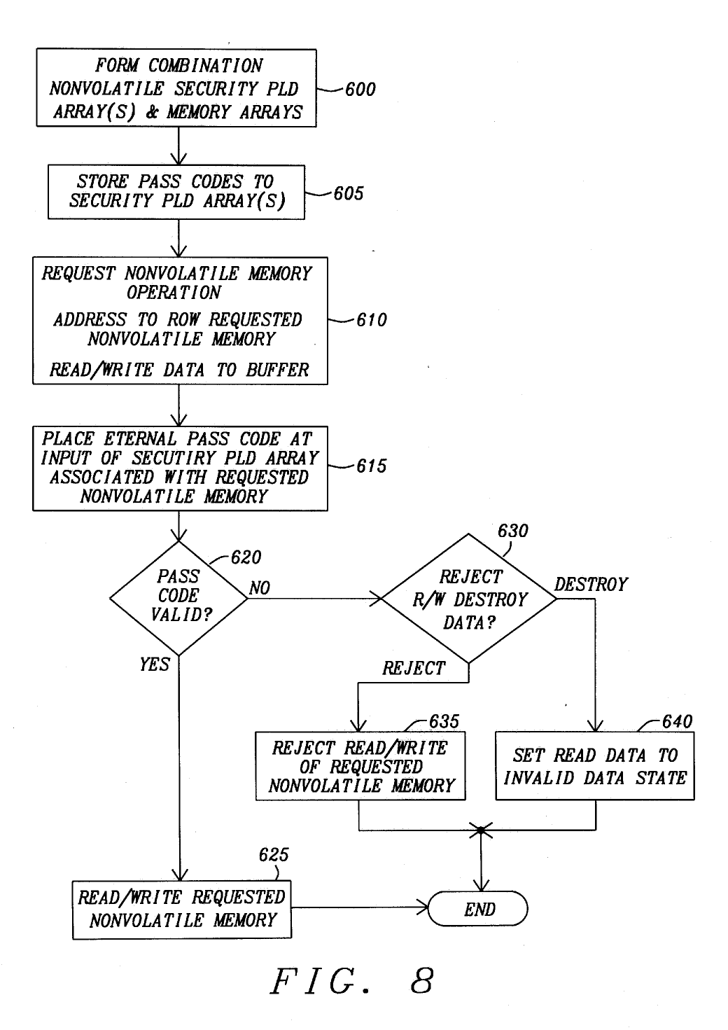

FIG. 8 is a flow chart for a third method of operation of an integrated circuit device incorporating security nonvolatile PLD array with at least one nonvolatile memory array. An integrated circuit formed (Box 600) of a combination of a security nonvolatile PLD array and at lease one nonvolatile memory array is provided. The combination nonvolatile memory integrated circuit includes a security nonvolatile PLD array 100 such as shown in FIGS. 3, 4, and 5 connected through an isolation circuit an a page buffer to the at least one nonvolatile memory array. As described above, the at least nonvolatile memory array may be a NAND Flash memory array, a one-transistor or two-transistor NOR Flash memory array, or an EEPROM memory array. The pass code is stored (Box 605) in the security nonvolatile PLD array by erasing and programming the security nonvolatile PLD cells with the pass code as described above.

A request for a nonvolatile memory operation is requested (Box 610). The row address of the requested data is applied to the requested nonvolatile memory and the data is written to a buffer (page buffer). The external pass code is applied (Box 615) to the primary variable input lines and the complementary variable input lines of the security nonvolatile PLD array associated with the requested nonvolatile memory array. The external pass code is compared (Box 620) with the stored pass code. If the external pass code matches the stored pass code the requested nonvolatile memory is written to or read from (Box 625) as requested.

If the external pass code is not matched with the stored pass code, the request is examined (Box 630) to determine if the execution is to be rejected or the data scrambled to be corrupted or destroyed to an invalid state. If the data is to be rejected, the read or write operation request is rejected (Box 635). If the data is to be destroyed, the data to read or written is set (Box 640) to an invalid state.

While the present disclosure has been particularly shown and described with reference to the preferred embodiments thereof, it will be understood by those skilled in the art that various changes in form and details may be made without departing from the spirit and scope of the present disclosure. The security nonvolatile PLD array of this disclosure is combined in the preferred embodiment with charge retaining nonvolatile memory arrays. However, it in keeping with the intent of the principles of this disclosure that the nonvolatile memory structures may be magneto-resistive memory structures or other data retentive structures. Further, it is in keeping with the intent of the principles of this disclosure that the memory structure may in fact be a volatile memory having an intimate connection to allow the product term bit lines to control the access to the volatile memory.

What is claimed is:

1. A memory access control apparatus in communication with a memory device for controlling access to the memory device comprising:
an array of nonvolatile programmable comparison cells that retain a programmed pass code for allowing access to the memory device;
a plurality of primary variable input terminals connected to the array of nonvolatile programmable comparison cells to provide an initializing pass code to be programmed to the array of nonvolatile programmable comparison cells;
a plurality of complementary variable input terminals connected to the array of nonvolatile programmable comparison cells to provide a complementary initializing pass code to be programmed to the array of nonvolatile programmable comparison cells; and
a plurality of control terminals in communication with the memory device for controlling the access to data within the memory device;
wherein when the memory device receives an access request pass code, the access request pass code is compared with the programmed pass code;
when there is a match between the access request pass code and the programmed pass code, the memory access control apparatus generates a match signal to be transmitted to the control terminals for allowing access to the memory device;
when there is no match between the access request pass code and the programmed pass code, the memory access control apparatus does not generate a match signal to be transmitted on the control terminals to the memory device and the request for access is rejected.

2. The memory access control apparatus of claim 1 wherein, when the access request pass code and programmed pass code do not match, the memory access control apparatus generated signals that are transferred to the control terminals for communication with the memory device that corrupt or destroy the data within the memory device.

3. The memory access control apparatus of claim 1 wherein the control terminals are connected to bit lines of the memory device and provides the necessary bit line signals for erasing, programming, and reading the memory device when the access request pass code matches the programmed pass code.

4. A security nonvolatile PLD cell comprising:
a pair of charge retaining transistors connected in a series string;
wherein, a drain of a first charge retaining transistor of the pair charge retaining transistors is connected to a product term bit line associated with and parallel to a column on which the security nonvolatile PLD cell resides;
wherein a source of a second of the charge retaining security nonvolatile PLD cell is connected to a product term source line associated with the associated security nonvolatile PLD cell and parallel with the associated product term bit line;
wherein a control gate of the first charge retaining transistor is connected to a primary variable input line and the control gate of the second charge retaining transistor is connected to a complementary variable input line, such that signals applied to the control gates are logically combined based on the programmed threshold voltage levels determined by the retained charge of the pair of charge retaining transistors to determine if a data state represented by the retained charge is equal to the data state of the primary and complementary variable input lines.

5. The security nonvolatile PLD cell of claim 4 wherein the source of the first charge retaining transistor and the drain of the second charge retaining transistor are commonly merged in a single drain/source region.

6. The security nonvolatile PLD cell of claim 4 wherein each of the pair of the charge retaining transistors comprises a floating gate to store the retained charge, wherein each floating gate is formed of a first polycrystalline silicon layer over a tunneling insulation layer wherein charge representing the data tunnels between the drain region and a channel region between the drains and the sources and the floating gate during programming and erasing security nonvolatile PLD cell.

7. The security nonvolatile PLD cell of claim 7 wherein each of the pair of the charge retaining transistors comprises a control gate formed of a second polycrystalline silicon layer on an interlayer dielectric placed over the floating gate of each charge retaining transistor.

8. The security nonvolatile PLD cell of claim 7 wherein the control gate of the first charge retaining transistor is connected to a primary variable input line for applying the primary input logic variable to the first charge retaining transistor and the control gate of the second charge retaining transistor is connected to the complementary variable input line for applying the complementary input logic variable to the second charge retaining transistor.

9. The security nonvolatile PLD cell of claim 8 wherein when each security nonvolatile PLD cell is programmed with a first programmed code when the first charge retaining transistor is written with a first state and the charge retaining transistor is written with a second state.

10. The security nonvolatile PLD cell of claim 9 wherein when the security nonvolatile PLD cell is programmed with a second programmed code when the first charge retaining transistor is written with the second state and the second charge retaining transistor is written with the first state.

11. The security nonvolatile PLD cell of claim 10 wherein the security nonvolatile PLD cell is operated by the steps of:
applying a query pass code as the primary variable input and a complementary pass code as the complementary variable input to the control gates of the first and second charge retaining transistors;
setting the product term source line connected to the source of the second charge retaining transistor at a first voltage level;
setting the product term bit line connected to the drain of the first charge retaining transistor at a second voltage level;
keeping the product term bit line connected to the first charge retaining transistor at the second voltage level, if the query pass code is correct;
turning on the pair of charge retaining transistors to conduct to connect the product term bit line to the product term source line such that the product term bit line approaches the voltage level of the first voltage level, if the query pass code is incorrect.

12. The security nonvolatile PLD cell of claim 11 wherein the first voltage level is the ground reference voltage level and the second voltage level is 1.0V.

13. The security nonvolatile PLD cell of claim 11 wherein the product term bit line is in communication directly to a bit line connected to a memory device and if the query pass code is correct, the data to be read or written is accessed correctly or if the query pass code is incorrect, the data to be read or written is corrupted and destroyed.

14. The security nonvolatile PLD cell of claim 11 further comprises a matching circuit connected to the product term bit line, wherein the matching circuit generates a match signal such that the match signal is active if the query pass code is correct and the match signal is inactive if the query pass code is incorrect.

15. The security nonvolatile PLD cell of claim 13 wherein the control gates of the security nonvolatile PLD cell are in communication directly to a pair of bit lines of the memory device.

16. The security nonvolatile PLD cell of claim 15 wherein the product term bit line is connected to a matching circuit and a match signal is active if the query pass code is correct and the match signal is inactive if the query pass code is incorrect, such that if the query pass code is correct, the data from the memory to be read or written is accessed correctly or if the query pass code is incorrect, the data to be read or written is corrupted and destroyed.

17. A security nonvolatile PLD apparatus comprising:
a plurality of primary variable input lines;
a plurality of complementary variable input lines parallel with the primary variable input lines such that each primary variable input line is associated with one complementary variable input line;
a plurality of product term bit lines placed orthogonally to the primary and complementary variable input lines;
a plurality of product term source lines placed orthogonally to the primary and complementary variable input lines and parallel with the plurality of product term source lines such that one product term source line is associated with one product term but line; and
an array of security nonvolatile PLD cells arranged in rows and columns such that the security nonvolatile PLD cells on each row are connected to the one of the primary variable input lines and one of the complementary variable input lines and the security nonvolatile PLD cells on each column are connected to one of the product term bit lines and to one of the product term source lines;
wherein each of the security nonvolatile PLD cells comprises:
a pair of charge retaining transistors connected in a series string;
wherein, a drain of a first charge retaining transistor of the pair of charge retaining transistors is connected to the product term bit line associated with and parallel to the column on which the security nonvolatile PLD cell resides;
wherein a source of a second charge retaining transistor is connected to one product term source line associated with the security nonvolatile PLD cell and parallel with the associated product term bit line;
wherein a control gate of each of the first charge retaining transistor is connected to one primary variable input line and the control gate of the second charge retaining transistor is connected to one complementary variable input line associated with the row on which the security nonvolatile PLD cell resides, such that signals applied to the control gates are logically combined based on the programmed threshold voltage levels determined by the retained charge of the pair of charge retaining transistors to determine if a data state represented by the retained charge is equal to the data state of the primary and complementary variable input lines.

18. The security nonvolatile PLD apparatus of claim 17 wherein the charge retaining transistors are charge storing FLOTOX transistors.

19. The security nonvolatile PLD apparatus of claim 17 wherein within each of the security nonvolatile PLD cells, the source of the first charge retaining transistor and the drain of the second charge retaining transistor are commonly merged in a single drain/source region.

20. The security nonvolatile PLD apparatus of claim 17 wherein each of the pair of the charge retaining transistors within each of the security nonvolatile PLD cells comprises a floating gate to store the retained charge, wherein each floating gate is formed of a first polycrystalline silicon layer over a tunneling insulation layer wherein charge representing the data tunnels between the drain region and a channel region between the drains and the sources and the floating gate during programming and erasing security nonvolatile PLD cell.

21. The security nonvolatile PLD apparatus of claim 20 wherein each of the pair of the charge retaining transistors within each of the security nonvolatile PLD cells comprises a control gate formed of a second polycrystalline silicon layer on an interlayer dielectric placed over the floating gate of each charge retaining transistor.

22. The security nonvolatile PLD apparatus of claim 21 wherein within each of the security nonvolatile PLD cells, the control gate of the first charge retaining transistor is connected to the primary variable input line associated with the row on which the security nonvolatile PLD cell resides for applying the primary input logic variable to the first charge retaining transistor and the control gate of the second charge retaining transistor is connected to the complementary variable input line associated with row on which the security nonvolatile PLD cell resides for applying the complementary input logic variable to the second charge retaining transistor.

23. The security nonvolatile PLD apparatus of claim 22 wherein when each security nonvolatile PLD cell is programmed with a first programmed code when the first charge retaining transistor is written with a first state and the second charge retaining transistor is written with a second state.

24. The security nonvolatile PLD apparatus of claim 22 wherein when each security nonvolatile PLD cell is programmed with a second programmed code when the first charge retaining transistor is written with the second state and the second charge retaining transistor is written with the first state.

25. The security nonvolatile PLD apparatus of claim 24 wherein the security nonvolatile PLD apparatus is operated by the steps of:
applying a query pass code as the primary input variables and a complementary pass code as the complementary input variables to the control gates of the first and second charge retaining transistors of each of the security nonvolatile PLD cells;
setting the product term source lines connected to the source of the second charge retaining transistors of each of the security nonvolatile PLD cells at a first voltage level;
setting the product term bit line connected to the drain of the first charge retaining transistor of each of the security nonvolatile PLD cells at a second voltage level;
keeping the product term bit line connected to the first charge retaining transistors for each column of the security nonvolatile PLD cells at the second voltage level, if the query pass code is correct;
turning on the pair of charge retaining transistors to conduct to connect the each product term bit line to the associated product term source line such that the product term bit lines approaches the voltage level of the first voltage level, if the query pass code is incorrect.

26. The security nonvolatile PLD apparatus of claim 25 wherein the first voltage level is the ground reference voltage level and the second voltage level is 1.0V.

27. The security nonvolatile PLD apparatus of claim 25 wherein the product term bit lines are in communication directly to each of a plurality of bit lines connected to a memory device and if the query pass code is correct, the data to be read or written is accessed correctly or if the query pass code is incorrect, the data to be read or written is corrupted and destroyed.

28. The security nonvolatile PLD apparatus of claim 25 further comprises a plurality of matching circuits connected such that each matching circuit is connected to one of the product term bit lines, wherein the matching circuit generates a match signal such that the match signal is active if the query pass code is correct and the match signal is inactive if the query pass code is incorrect.

29. The security nonvolatile PLD apparatus of claim 27 wherein the primary variable input lines and its complementary variable input lines connected to the control gates of each row of the security nonvolatile PLD cells are in communication directly to pairs of bit lines for two columns of the memory device.

30. The security nonvolatile PLD apparatus of claim 29 wherein each of the product term bit lines is connected to a matching circuit and a match signal is active if the query pass code is correct and the match signal is inactive if the query pass code is incorrect, such that if the query pass code is correct, the data from the memory to be read or written is accessed correctly or if the query pass code is incorrect, the data to be read or written is corrupted and destroyed.

31. An integrated circuit comprising:
at least one memory array for retaining digital data; and
a memory access control apparatus in communication with at least one memory array for controlling access to the at least one memory array, comprising:
an array of nonvolatile programmable comparison cells that retain a programmed pass code for allowing access to the at least one memory array;
a plurality of primary variable input terminals connected to the array of nonvolatile programmable comparison cells to provide an initializing pass code to be programmed to the array of nonvolatile programmable comparison cells;
a plurality of complementary variable input terminals connected to the array of nonvolatile programmable comparison cells to provide a complementary initializing pass code to be programmed to the array of nonvolatile programmable comparison cells; and
a plurality of control terminals in communication with the at least one memory array for controlling the access to data within the at least memory array;
wherein when the array of nonvolatile programmable comparison cells receives an access request pass code, the access request pass code is compared with the programmed pass code;
when there is a match between the access request pass code and the programmed pass code, the memory access control apparatus generates a match signal to be transmitted to the control terminals for allowing access to the at least memory array;
when there is no match between the access request pass code and the programmed pass code, the memory access control apparatus does not generate a match signal to be transmitted on the control terminals to the at least memory array and the request for access is rejected.

32. The integrated circuit of claim 31 wherein when the access request pass code and programmed pass code do not match, the memory access control apparatus generated signals that are transferred to the control terminals for communication with the at least memory array that corrupt or destroy the data within the memory device.

33. The integrated circuit of claim 31 wherein the control terminals are connected to bit lines of the memory device and provides the necessary bit line signals for erasing, programming, and reading the at least memory array when the access request pass code matches the programmed pass code.

34. The integrated circuit of claim 31 wherein the at least one memory array is a NAND Flash nonvolatile memory array, a one-transistor or two transistor NOR Flash nonvolatile memory array, or an EEPROM nonvolatile memory array.

35. The integrated circuit of claim 31 wherein the at least one memory array provides storage for byte structured data, program code data, or large audio or video data structures.

36. The integrated circuit of claim 31 wherein the array of nonvolatile programmable comparison cells is an array of security nonvolatile PLD cells arranged in rows and columns such that the security nonvolatile PLD cells on each row are connected to one of a plurality primary variable input lines connected to one of the plurality of primary variable input terminals and one of a plurality of complementary variable input lines connected to one of the plurality of complementary variable input terminals and the security nonvolatile PLD cells on each column are connected to one of a plurality of product term bit lines connected to one of the control terminals and connected to one of a plurality of product term source lines connected to one of the control terminals;
wherein each of the security nonvolatile PLD cells comprises:
a pair of charge retaining transistors connected in a series string;
wherein, a drain of a first charge retaining transistor of the pair of charge retaining transistors is connected to the product term bit line associated with and parallel to the column on which the security nonvolatile PLD cell resides;
wherein a source of a second charge retaining transistor is connected to one product term source line associated with the security nonvolatile PLD cell and parallel with the associated product term bit line;
wherein a control gate of each of the first charge retaining transistor is connected to one primary variable input line and the control gate of the second charge retaining transistor is connected to one complementary variable input line associated with the row on which the security nonvolatile PLD cell resides, such that signals applied to the control gates are logically combined based on the programmed threshold voltage levels determined by the retained charge of the pair of charge retaining transistors to determine if a data state represented by the retained charge is equal to the data state of the primary and complementary variable input lines.

37. The integrated circuit of claim 36 wherein the charge retaining transistors are charge storing FLOTOX transistors.

38. The integrated circuit of claim 36 wherein within each of the security nonvolatile PLD cells, the source of the first charge retaining transistor and the drain of the second charge retaining transistor are commonly merged in a single drain/source region.

39. The integrated circuit of claim 36 wherein each of the pair of the charge retaining transistors within each of the security nonvolatile PLD cells comprises a floating gate to store the retained charge, wherein each floating gate is formed of a first polycrystalline silicon layer over a tunneling insulation layer wherein charge representing the data tunnels between the drain region and a channel region between the drains and the sources and the floating gate during programming and erasing security nonvolatile PLD cell.

40. The integrated circuit of claim 29 wherein each of the pair of the charge retaining transistors within each of the security nonvolatile PLD cells comprises a control gate formed of a second polycrystalline silicon layer on an interlayer dielectric placed over the floating gate of each charge retaining transistor.

41. The integrated circuit of claim 40 wherein within each of the security nonvolatile PLD cells, the control gate of the first charge retaining transistor is connected to the primary variable input line associated with the row on which the security nonvolatile PLD cell resides for applying the primary input logic variable to the first charge retaining transistor and the control gate of the second charge retaining transistor is connected to the complementary variable input line associated with row on which the security nonvolatile PLD cell resides for applying the complementary input logic variable to the second charge retaining transistor.

42. The integrated circuit of claim 41 wherein when each security nonvolatile PLD cell is programmed with a first programmed code when the first charge retaining transistor is written with a first state and the second charge retaining transistor is written with a second state.

43. The integrated circuit of claim 42 wherein when each security nonvolatile PLD cell is programmed with a second programmed code when the first charge retaining transistor is written with the second state and the second charge retaining transistor is written with the first state.

44. The integrated circuit of claim 43 wherein the memory access control apparatus is operated by the steps of:
applying a query pass code to the primary variable input terminals and a complementary pass code as the complementary variable input terminals and thus to the control gates of the first and second charge retaining transistors of each of the security nonvolatile PLD cells;
setting the control terminals connected to the product term source line connected to the source of the second charge retaining transistors of each of the security nonvolatile PLD cells at a first voltage level;
setting the control terminals connected to the product term bit line connected to the drain of the first charge retaining transistor of each of the security nonvolatile PLD cells at a second voltage level;
keeping the product term bit line connected to the first charge retaining transistors for each column of the security nonvolatile PLD cells at the second voltage level, if the query pass code is correct;
turning on the pair of charge retaining transistors to conduct to connect the each product term bit line to the associated product term source line such that the product term bit lines approaches the voltage level of the first voltage level, if the query pass code is incorrect.

45. The integrated circuit of claim 44 wherein the first voltage level is the ground reference voltage level and the second voltage level is approximately 1.0V.

46. The integrated circuit of claim 44 wherein the product term bit lines are in communication directly to each of a plurality of bit lines connected to a memory device and if the query pass code is correct, the data to be read or written is accessed correctly or if the query pass code is incorrect, the data to be read or written is corrupted and destroyed.

47. The integrated circuit of claim 44 further comprises a plurality of matching circuits connected such that each matching circuit is connected to one of the product term bit lines, wherein the matching circuit generates a match signal such that the match signal is active if the query pass code is correct and the match signal is inactive if the query pass code is incorrect.

48. The integrated circuit of claim 46 wherein the primary variable input lines and its complementary variable input lines connected to the control gates of each row of the security nonvolatile PLD cells are in communication directly to pairs of bit lines for two columns of the memory device.

49. The integrated circuit of claim 38 wherein each of the product term bit lines is connected to a matching circuit and a match signal is active if the query pass code is correct and the match signal is inactive if the query pass code is incorrect, such that if the query pass code is correct, the data from the memory to be read or written is accessed correctly or if the query pass code is incorrect, the data to be read or written is corrupted and destroyed.

50. The integrated circuit of claim of claim 32 further comprising a isolation circuit placed between the memory access control apparatus and the at least one memory array to prevent corruption of data during erasing and programming of memory access control apparatus and the at least one memory array by effectively disconnecting the memory access control apparatus from the at least one memory array.

51. The integrated circuit of claim 31 further comprising a page buffer for sensing data read from the at least one memory array and holding the initializing pass code during the programming of the memory access control apparatus.

52. A method of operating a provided integrated circuit having a memory access control apparatus in communication with at least one memory array comprising the steps of:
writing an initializing pass code program the memory access control apparatus with a programmed pass code;
applying a access request pass code to the memory access control apparatus;
comparing the query pass code with the stored pass code within the memory access control apparatus
generating a match signal to be transmitted to the at least one memory array for allowing access to the memory device when there is a match between the access request pass code and the programmed pass code;
generating a non-match signal to be transmitted to the at least one memory array and the request for access is rejected when there is no match between the access request pass code and the programmed pass code.

53. The method of claim 52 wherein the at least one memory array is a NAND Flash nonvolatile memory array, a one-transistor or two transistor NOR Flash nonvolatile memory array, or an EEPROM nonvolatile memory array.

54. The method of claim 52 wherein the at least one memory array is wherein the at least one memory array provides storage for byte structured data, program code data, or large audio or video data structures.

55. The method of claim 52 wherein memory access control apparatus comprises an array of security nonvolatile PLD cells arranged in rows and columns such that the security nonvolatile PLD cells on each row are connected to one of a plurality primary variable input lines connected and one of a plurality of complementary variable input lines to receive the initializing pass code and the query pass code and the security nonvolatile PLD cells on each column are connected to one of a plurality of product term bit lines connected to provide the match signal and connected to one of a plurality of product term source lines connected to provide the non-match signal;
wherein each of the security nonvolatile PLD cells comprises:
a pair of charge retaining transistors connected in a series string;
wherein, a drain of a first charge retaining transistor of the pair of charge retaining transistors is connected to the product term bit line associated with and parallel to the column on which the security nonvolatile PLD cell resides;
wherein a source of a second charge retaining transistor is connected to one product term source line associated with the security nonvolatile PLD cell and parallel with the associated product term bit line;
wherein a control gate of each of the first charge retaining transistor is connected to one primary variable input line and the control gate of the second charge retaining transistor is connected to one complementary variable input line associated with the row on which the security nonvolatile PLD cell resides, such that signals applied to the control gates are logically combined based on the programmed threshold voltage levels determined by the retained charge of the pair of charge retaining transistors to determine if a data state represented by the retained charge is equal to the data state of the primary and complementary variable input lines.

56. The method of claim 55 wherein when each security nonvolatile PLD cell is programmed with a first programmed code when the first charge retaining transistor is written with a first state and the second charge retaining transistor is written with a second state.

57. The method of claim 56 wherein when each security nonvolatile PLD cell is programmed with a second programmed code when the first charge retaining transistor is written with the second state and the second charge retaining transistor is written with the first state.

58. The method of claim 57 wherein comparing the query pass code with the stored pass code, generating the match signal, and generating the non-match signal comprises the steps of:
applying the query pass code to the primary variable input lines and a complementary pass code as the complementary variable input lines and thus to the control gates of the first and second charge retaining transistors of each of the security nonvolatile PLD cells;
setting the product term source line connected to the source of the second charge retaining transistors of each of the security nonvolatile PLD cells at a first voltage level;
setting the control terminals connected to the product term bit line connected to the drain of the first charge retaining transistor of each of the security nonvolatile PLC cells at a second voltage level;
keeping the product term bit line connected to the first charge retaining transistors for each column of the security nonvolatile PLD cells at the second voltage level, if the query pass code is correct;
turning on the pair of charge retaining transistors to conduct to connect the each product term bit line to the associated product term source line such that the product term bit lines approaches the voltage level of the first voltage level, if the query pass code is incorrect.

59. The method of claim 58 wherein the first voltage level is the ground reference voltage level and the second voltage level is approximately 1.0V.

60. The method of claim 58 wherein the product term bit lines are in communication directly to each of a plurality of bit lines connected to a memory device and if the query pass code is correct, the data to be read or written is accessed correctly or if the query pass code is incorrect, the data to be read or written is corrupted and destroyed.

61. The method of claim 58 wherein a plurality of matching circuits are connected such that each matching circuit is connected to one of the product term bit lines, wherein the matching circuit generates the match signal such that the match signal is active if the query pass code is correct and the match signal is inactive to form the non-match signal if the query pass code is incorrect.
